(19) United States
(12) Patent Application Publication
(10) Pub. No.: US 2014/0339614 A1
(43) Pub. Date: Nov. 20, 2014

(54) IMAGE SENSOR AND METHOD OF FABRICATING THE SAME

(71) Applicant: SHANGHAI ADVANCED RESEARCH INSTITUTE, CHINESE ACA- DEMY OF SCIENCES, Shanghai (CN)

(72) Inventors: Na Fang, Shanghai (CN); Hui Wang, Shanghai (CN); Jie Chen, Shanghai (CN); Li Tian, Shanghai (CN); Tao Ren, Shanghai (CN)

(21) Appl. No.: 14/369,938

(22) PCT Filed: Dec. 24, 2012
(86) PCT No.: PCT/CN2012/087254

§ 371 Date: Jun. 30, 2014

(30) Foreign Application Priority Data
Dec. 30, 2011 (CN) 201110455204.0
Dec. 30, 2011 (CN) 201110455382.3

(51) Int. Cl. H01L 27/146; H04N 5/378

(52) U.S. Cl. CPC H01L 27/14643; H04N 5/378; H01L 27/14689; H01L 27/14603
USPC 257/292; 438/73

(57) ABSTRACT

The present invention provides an image sensor and a method of fabricating the same. The image sensor comprises a semiconductor substrate, a photosensitive component, and a pixel-readout circuit, characterized in that, the semiconductor substrate comprises a supporting substrate, a first insulating buried layer, a first semiconductor layer, a second insulating buried layer, and a second semiconductor layer covered on the semiconductor substrate in sequence; the first semiconductor layer and the second semiconductor layer have different thicknesses, such that the photosensitive component is in the thicker semiconductor layer, and the pixel-readout circuit is in the thinner semiconductor layer. To realize the image sensor mentioned above, two different methods are provided. Ion implantation and bonding method are used respectively to provide the first and second insulating buried layers, and the first and second semiconductor layer substrates, and then the image sensor is fabricated. The image sensor in the present invention has a well anti-radiation character and a well semiconductor character, and a photosensitive zone that has higher light absorption rate.

### TECHNICAL FIELD

The present invention is about a kind of image sensor and method of fabricating the same, especially for an image sensor with dual insulating buried layers and method of fabricating the same, which belongs to semiconductor technical field.

### BACKGROUND TECHNOLOGY

In general, image sensor is a kind of semiconductor device for transforming an optical image to electrical signals. Image sensors are divided into a charge coupled device (CCD) and a complementary metal-oxide semiconductor (CMOS) image sensor. Recently, the CMOS image sensor is concerned as next generation image sensor to overcome drawbacks of the CCD. The CMOS sensor comprises a photodiode and a metal-oxide semiconductor (MOS) transistor in a mono-pixel, and electrical signals of each mono-pixel can be detected continuously by switching mode, to obtain an image.

Active pixel sensor (APS), which is divided into image sensor with three transistors (a 3T type which comprises a reset transistor, an amplified transistor and a row select transistor) and image sensor with four transistors (a 4T type comprises a transfer transistor, a reset transistor, an amplified transistor and a row select transistor), is commonly used as the CMOS image sensor in prior art.

Silicon-On-Insulator (SOI) technology is to provide a buried oxide layer between a top silicon layer and a substrate. With a semiconductor film on the buried oxide layer, SOI material has some advantages beyond compare to traditional bulk silicon materials: it can realize dielectric isolation of inter-components in ICs, to completely avoid latch-up effect in CMOS circuits in the bulk silicon material; the ICs with the present material also have advantages such as low parasitical capacitance, high integrated density, fast speed, simple process, low short channel effect, and especially suitable for circuits with low voltage and low energy consumption.

Two kinds of the CMOS image sensor based on SOI process are shown as followed:

A photodiode is set in a bulk silicon wafer in the first kind of CMOS sensor. As illustrated in FIG. 1, the 4T type is adopted in basic photosensitive unit (principle of the 3T type pixel structure is omitted for similar to the 4T type), and pixel structure comprises: a P-doped silicon substrate 101 with SOI structure, an insulator layer (SiO₂ in general) 102, a P-doped top silicon layer 104, an N-doped well zone 107 in the silicon substrate, a P-doped zone 108 above the N-doped well zone and at surface of the silicon substrate, a transfer transistor 105, a floating diffusion zone 106, a SiO₂ layer 109 above the silicon substrate and under the transfer transistor, and components 103 on top silicon layer for optical and electrical signal treatment circuit (only a reset transistor is illustrated in FIG. 1, and an amplified transistor and a row select transistor are not illustrated). Wherein, the whole N-doped well zone 107 and a part of the P-doped zone 108 and the silicon substrate 101 make up an active photosensitive zone 110, and the photodiode is set in the photosensitive zone 110.

Operating principle of it is as followed: firstly the reset transistor of the components 103 for optical and electrical signal treatment circuit absorbs all of electrons in the floating diffusion zone 106 to a power, to pull up its potential; photons irradiate to the photosensitive zone 110 when starting exposure, and then electron-hole pairs generate in it; a high potential adds to the transfer transistor 105 after the exposure, to shift photoelectrons in the photosensitive zone 110 to the floating diffusion zone 106 to pull down its potential; a photo voltage is output through the amplified transistor and the row select transistor (not shown) in the components 103 for optical and electrical signal treatment circuit.

A photodiode is set in a top silicon layer (semiconductor layer) in the second kind of CMOS sensor. As illustrated in FIG. 2, pixel structure comprises: a silicon substrate 201 with SOI structure, an insulator layer 202, a P-doped top silicon layer 203, an N-doped zone 204 in the top silicon layer and near surface, and an optical and electrical signal treatment circuit 206 on top silicon layer. Wherein, depletion part of the N-doped zone 204 nearing the top silicon layer 203 and depletion part of the top silicon layer 203 nearing the N-doped zone 204 make up an active photosensitive zone 205, and the entire active photosensitive zone 205 is in the top silicon layer of the SOI structure. Doping concentration of the N-doped zone 204 is 3 orders of magnitude higher than it of the top silicon layer 203, to make most part of the depletion zone is in the top silicon layer 203.

Photo carriers are collected through the active photosensitive zone 205 in the top silicon layer in the CMOS image sensor based on SOI process as illustrated in FIG. 2, and other operating modes are same to the image sensor in FIG. 1.

The prior arts mentioned above have disadvantages at least as follows.

In the first kind of CMOS image sensor mentioned above, high-energy particles can irradiate into the silicon substrate 101 to generate a large number of electron-hole pairs when the image sensor is put into irradiation environment, for the photosensitive zone is in the silicon substrate and touch with it directly. Wherein the high-energy particle can easily pass through PN junction potential barrier made up by the silicon substrate 101 and N-doped well zone 107, and then enters into the N-dope well zone 107, which disturbs signals for the image, and reduces a signal-noise ratio and dynamic range of the image.

In the second kind of CMOS image sensor mentioned above, a thickness of the top silicon layer 203 is commonly less than 200 nm for the photosensitive zone is in the top silicon layer and full-depletion SOI devices are used, which restricts depth of the active photosensitive zone 205, to reduce photo absorption rate of the image sensor especially having the ultra low rate and bad quality image for the red, orange and yellow light with wave length larger than 600 nm.

So, a CMOS image sensor with large active photosensitive depth, large signal-noise ratio, and dynamic range is really needed.

### SUMMARY OF THE INVENTION

Regarding the disadvantages in the prior art mentioned above, aim of the present invention is to provide a image sensor and a method for fabricating the same, to solve the problem that the image sensor in the prior art has a low signal-noise ratio and dynamic range for its bad anti-irradiation ability, and the problem that the photo absorption rate is low for the restriction to the depth of the active photosensitive zone.

To realize the aims above and other related aims, the present invention provides an image sensor comprising a semiconductor substrate, a photosensitive component, and a pixel-readout circuit, characterized in that, the semiconductor substrate comprises a supporting substrate, and a first insulating buried layer, a first semiconductor layer, a second insulating buried layer, and a second semiconductor layer covered on the semiconductor substrate in sequence; the first semiconductor layer and the second semiconductor layer have different thicknesses, and the photosensitive component is in the thicker semiconductor layer, and the pixel-readout circuit is in the thinner semiconductor layer.

Optionally, the first semiconductor layer is thicker than the second semiconductor layer, the first semiconductor layer is photosensitive layer, and the second semiconductor layer is a pixel-readout circuit layer.

Optionally, the second semiconductor layer is thicker than the first semiconductor layer, the second semiconductor layer is photosensitive layer, and the first semiconductor layer is a pixel-readout circuit layer.

Furthermore, the pixel-readout circuit is the 4T type CMOS pixel-readout circuit, which comprises a transfer transistor, a reset transistor, an amplified transistor and a row select transistor, wherein the transfer transistor is fabricated in the photosensitive layer, and the reset transistor, amplified transistor and row select transistor are fabricated in the pixel-readout circuit layer.

Optionally, a material for the first and second semiconductor layers is any one kind of silicon, strained silicon, germanium, or silicon germanium.

Optionally, thickness of the photosensitive layer is 300 nm-10 μm, and thickness of the pixel-readout circuit layer is 100 nm-300 nm.

The present invention also provides a method of fabricating the image sensor comprising following steps:

A, providing a semiconductor substrate with the first insulating buried layer, wherein the first insulating buried layer divides the semiconductor substrate into the supporting substrate and a top semiconductor layer;

B, fabricating the second insulating buried layer in the top semiconductor layer, to electrically isolate the top semiconductor layer to the first semiconductor layer and the second semiconductor layer, wherein the first semiconductor layer and the second semiconductor layer have different thicknesses;

C, defining two zones as a first zone and a second zone on a surface of the second semiconductor layer, wherein a window in the first zone is fabricated by etching to expose surface of the first semiconductor layer; and

D, the first semiconductor layer and the second semiconductor layer have different thicknesses, and fabricating a photosensitive component and a pixel-readout circuit in the thicker and thinner semiconductor layers respectively.

Furthermore, the method is by an ion implantation in the top semiconductor layer for fabricating the second insulating buried layer.

Optionally, thickness of the semiconductor layer is 0.5 μm-10 μm in the semiconductor substrate, the first semiconductor layer is thicker than the second semiconductor layer, and thickness of the second semiconductor layer is 100 nm-300 nm.

Optionally, thickness of the semiconductor layer is 0.2 μm-0.5 μm in the semiconductor substrate, the second semiconductor layer is thicker than the first semiconductor layer, and thickness of the first semiconductor layer is 100 nm-300 nm. At this moment, the method after the step B and before the step C comprises step C1: epitaxy on surface of the second semiconductor layer, to make the thickness is 0.3 μm-10 μm.

To realize the aims above and other related aims, the present invention also provides a method of fabricating the image sensor which comprises the following steps:

A, providing a first semiconductor substrate and a second semiconductor substrate, wherein, the first semiconductor substrate comprises a first supporting substrate, a first insulating buried layer on the surface of the first supporting substrate, and a first top semiconductor layer on the surface of the first insulating buried layer;

B, fabricating a second insulating buried layer on the surface of the first semiconductor substrate or the second semiconductor substrate;

C, bonding the first semiconductor substrate and the second semiconductor substrate, with the second insulating buried layer between the first top semiconductor layer and the second semiconductor substrate;

D, thinning the second semiconductor substrate to fabricate the second top semiconductor layer with different thicknesses to the first top semiconductor layer, wherein the thicker one in the first top semiconductor layer and the second top semiconductor layer is a thick film layer and the other one is a thin film layer on the contrary;

E, defining zone I and zone II on a surface of the second top semiconductor layer, and opening a window in the zone I until the surface of the first top semiconductor layer is exposed; and

F, fabricating photosensitive components and the pixel-readout circuit in the zone I and zone II, wherein the photosensitive components are fabricated in the thick film layer and neighboring components are isolated, to finish fabricating the image sensor.

Optionally, the first top semiconductor layer is a thin film layer with thickness of 0.1 μm-0.3 μm, the second top semiconductor layer is a thick film layer with thickness of 0.3 μm-10 μm.

Optionally, the first top semiconductor layer is a thick film layer with thickness of 0.3 μm-10 μm, the second top semiconductor layer is a thin film layer with thickness of 0.1 μm-0.3 μm.

Optionally, a material for the first top semiconductor layer and the second top semiconductor layer is a semiconductor material for fabricating semiconductor components, at least comprises any one kind of silicon, strained silicon, germanium, or silicon germanium; and the first supporting substrate is a common semiconductor substrate, at least comprises a silicon substrate or a sapphire substrate.

Optionally, the photosensitive component comprises a photodiode or a photo-electric gate at least in step 6); and the pixel-readout circuit is the 3T or 4T type pixel-readout circuit, wherein the 3T pixel-readout circuit comprises a reset transistor, an amplified transistor and a row select transistor, and the 4T pixel-readout circuit comprises a transfer transistor, a reset transistor, an amplified transistor and a row select transistor.

Optionally, the reset transistor, amplified transistor and row select transistor of the pixel-readout circuit are fabricated in the thin film layer; and the transfer transistor is fabricated in the thick film layer if the pixel-readout circuit is the 4T type pixel-readout circuit.

Optionally, the second semiconductor substrate is semiconductor substrate with an insulating buried layer, as least comprises a silicon-on-insulator or a germanium-on-insulator; and the thinning process in step 4) comprises etching the supporting substrate and the insulating buried layer of the second semiconductor substrate in sequence.

Optionally, the thinning process in the step 4) also comprises a planarization process after etching.

Optionally, if the first top semiconductor layer is a thin film layer and the second top semiconductor layer is a thick film layer, the second semiconductor substrate is a common semiconductor substrate, which comprises a silicon substrate or a sapphire substrate at least; and the thinning process in step 4) comprises etching process forward and planarization process afterward.

Optionally, the second semiconductor substrate is a common semiconductor substrate, which comprises a silicon substrate or a sapphire substrate at least; and the step 1) further comprises H ions implantation to a surface of the second semiconductor substrate, and depth of implantation is the thickness of the second top semiconductor layer in the step 4); and high temperature annealing is used for thinning in the step 4), to implant the H ions to location of dielectric layer and form continuous bubble layer, and then the second semiconductor substrate is split at the location of dielectric layer formed by the H ions implantation, to form the second top semiconductor layer.

In summary, the image sensor in the present invention has the advantages below:

1) The photosensitive components have a deeper PN junction depletion zone and a higher photo absorbing rate, for fabricated in the top semiconductor layer with the thick film layer.

2) The pixel-readout circuit has full depleted MOS transistors and the circuit is high speed, low energy consumption, avoiding latch-up effect, for fabricated in the top semiconductor layer with a thin film layer.

3) The photosensitive components and the pixel-readout circuit of the image sensor are electrically isolated by the first insulating buried layer and the second insulating buried layer to the first supporting substrate and the second supporting substrate, to enhance their ability of anti high energy particles radiation

### BRIEF DESCRIPTION OF THE DRAWINGS

FIG. 1 illustrates a cross section diagram of a 4T type CMOS image sensor in prior art;

FIG. 2 illustrates a cross section diagram of a 3T type CMOS image sensor in prior art;

FIG. 3 illustrates a diagram of an embodiment of an image sensor in the present invention;

FIG. 4 illustrates a circuit diagram of a 4T type CMOS image sensor in an example;

FIG. 5 illustrates a circuit diagram of a 3T type CMOS image sensor in an example;

FIG. 6 illustrates a cross section diagram of an embodiment of an image sensor in the present invention, and some parts are not illustrated to outline the other parts;

FIG. 7 illustrates a cross section diagram of another embodiment of an image sensor in the present invention;

FIGS. 8a to 8e are structure diagrams of steps fabricating first image sensor provided by the present invention;

FIGS. 9a to 9f are structure diagrams of steps fabricating second image sensor in example 1 provided by the present invention;

FIGS. 10a to 10f are structure diagrams of steps fabricating second image sensor in example 2 provided by the present invention;

FIGS. 11a to 11e are structure diagrams of steps fabricating second image sensor in example 3 provided by the present invention;

FIGS. 12a to 12f are structure diagrams of steps fabricating second image sensor in example 4 provided by the present invention.

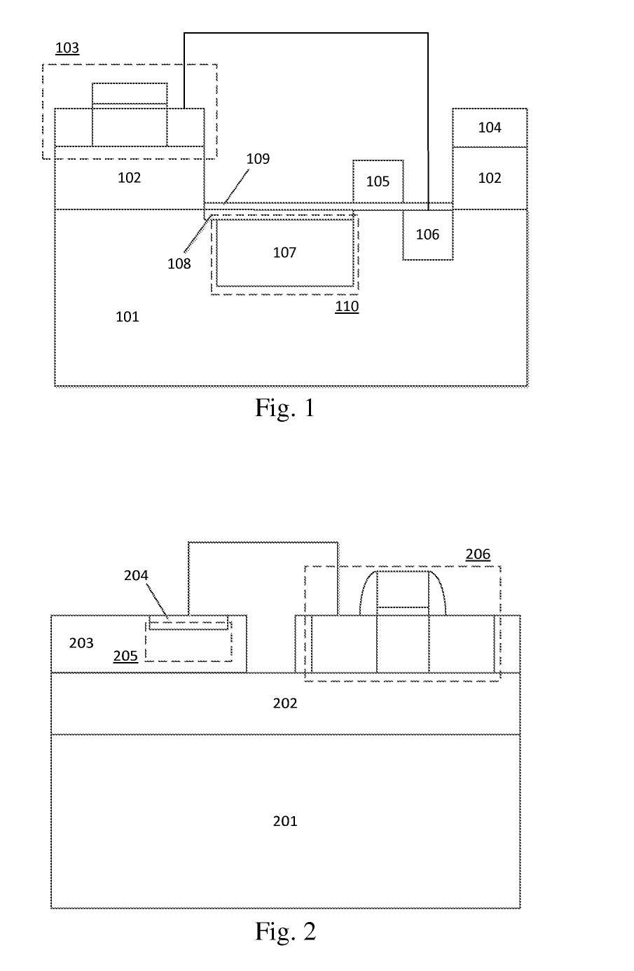

### EMBODIMENTS

Embodiment of the present invention is illustrated by particular examples below, and other advantages and effects can be easily found by persons skilled in this art though contents disclosed by the present description. The present invention can also be operated or applied by other different embodiments, and all the details in the present description can also be modified or adjusted based on different opinions and applications without departing from spirits of the present invention.

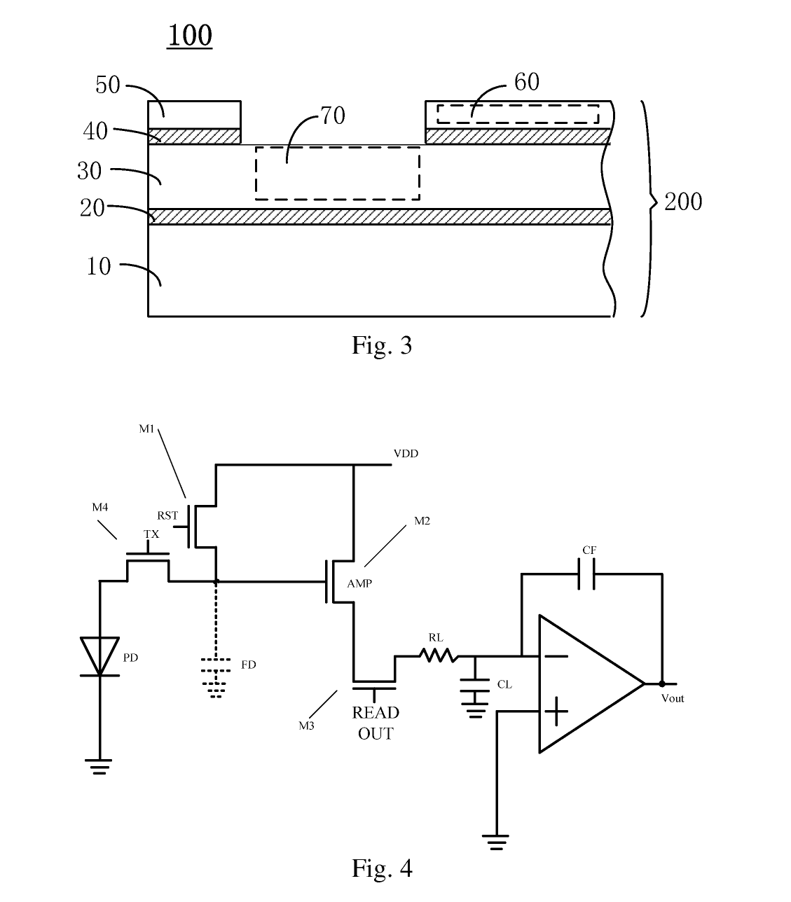

FIG. 3 illustrates a diagram of an image sensor in an embodiment of the present invention. As illustrated in the figure, the image sensor 100 in this embodiment comprises: a semiconductor substrate 200, a photosensitive device 70, and a pixel-readout circuit 60. The semiconductor substrate 200 comprises a supporting substrate 10, and the supporting substrate 10 is covered in sequence by a first insulating buried layer 20, a first semiconductor layer 30, a second insulating buried layer 40, and a second semiconductor layer 50.

The first semiconductor layer 30 has a larger silicon thickness, and preferably, a range of the thickness is 300 nm-10 μm.

The second semiconductor layer 50 has a smaller silicon thickness, and preferably, a range of the thickness is 100 nm-300 nm.

Material of the first semiconductor layer 30 or the second semiconductor layer 50 is selected independently in one of silicon, strained silicon, germanium, and silicon-germanium, or another semiconductor material commonly used for fabricating semiconductor devices. Preferably, the supporting substrate 10 is anyone in silicon, germanium, silicon-germanium, or sapphire, and the first or second insulating buried layer is selected independently in one of silicon oxide, silicon nitride, and silicon oxide and nitride, or a stack structure consisting by them.

The photosensitive device 70 is in the first semiconductor layer 30. Preferably, the photosensitive device may be a photodiode formed by a PN junction, or a PIN diode, or a photogate.

The pixel-readout circuit 60 is in the second semiconductor layer 50, and the pixel-readout circuit comprises a CMOS circuit consisted by MOS transistors. Optionally, the pixel-readout circuit is the 3T or 4T structure, or other structure, for instance, a 5T structure.

FIG. 4 illustrates a circuit diagram in an embodiment for a 4T type CMOS image sensor.

As illustrated in FIG. 4, one terminal of a photosensitive diode (PD) is at earth potential, and another terminal connects to a transfer transistor in the structure of the 4T type CMOS image sensor. One of the source or drain of a reset transistor M1 and amplified transistor M2 connect to power VDD together, and gate of the reset transistor M1 connects to a reset line providing a reset signal. Source of a row select transistor M3 connects to the source of the amplified transistor M2, and gate of the row select transistor M3 connects to a row select line providing a select signal (as a readout signal). Gate of a transfer transistor M4 connects to a transfer control signal and one of source or drain connects to the non earth potential terminal of the photosensitive diode PD, and another connects to gate of the amplified transistor M2. One terminal of it connected to gate of a second MOS transistor APS is floating diffusion zone, and a PN junction capacitance, as a capacitance FD, is made up by it and the semiconductor substrate, to storage photo charge.

Operating principle of it is as followed: the gate of the reset transistor M1 receives a pulse signal with high potential without lighting, using for resetting the floating diffusion zone of the drain of the transfer transistor M4, to set it to high potential; the reset process finishes when the pulse signal to the gate of the reset transistor M1 turns to low potential, and then the photosensitive diode PD receives lighting in a default time and generates carriers for the lighting; the gate of the transfer transistor M4 receives the pulse signal with high potential, and transfer the carriers from the photosensitive diode PD to the floating diffusion zone FD; the row select transistor M3 receives the pulse signal with high potential, and the carriers put out from the floating diffusion zone FD through the amplified transistor M2 and the row select transistor M3, and then a collecting and transferring process for a photo signal is finished

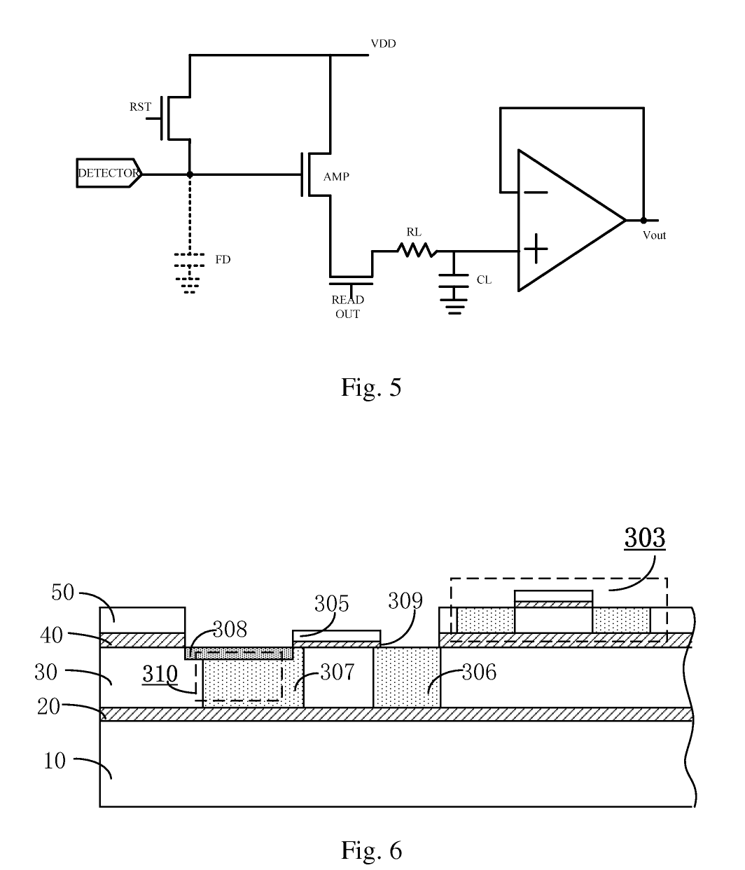

FIG. 5 illustrates a circuit diagram in an embodiment for a 3T type CMOS image sensor. As illustrated in FIG. 5, structure and operating principle of the 3T type CMOS image sensor are similar to that of the 4T type CMOS image sensor, just excluding the transfer transistor TX (M4). Free charge from the photosensitive diode (as photo electronics detector) for receiving lighting is read out directly through the amplified transistor AMP and the row select transistor, which is omitted here.

FIG. 6 illustrates a structure diagram of an image sensor in an embodiment of the present invention. Only partial structure relating to the present invention is shown to clarify, and others (such as isolation layer for components and so on) are not shown for the prior art.

As illustrated in FIG. 6, an image sensor comprises:

a semiconductor comprising a supporting substrate 10, a first insulating buried layer 20, a first semiconductor layer 30 covering the first insulating buried layer 20, a second insulating buried layer 40 on the first semiconductor layer 30, a second insulating buried layer 50 covering the second insulating layer 40;

a photosensitive component on the first semiconductor layer 30, and the photosensitive component is a photodiode 310 with a PN junction, which comprises a first conductive type doped zone 307 in the first semiconductor layer 30, and a second conductive type doped zone 308 in the first conductive type doped zone 307 and surface of the first semiconductor layer 30; and

a readout circuit on the second insulating buried layer 50.

As the best embodiment, the first semiconductor layer 30 and the second semiconductor layer 50 are P-type semiconductor substrates, and the first semiconductor layer 30 is thicker than the second semiconductor layer 50. The thickness of the first semiconductor layer 30 is 300 nm-10 μm, and the thickness of the second semiconductor layer 50 is 100 nm-300 nm. The first conductive type is N-type, and the second conductive type is P-type.

Preferably, as illustrated in FIG. 6, the thickness of the first semiconductor layer 30 is 2 μm-3 μm, and the thickness of the second semiconductor layer 50 is 150 nm-200 nm. The pixel-readout circuit is the 4T type CMOS pixel-readout circuit, which comprises: the reset transistor, the amplified transistor, the row select transistor and the transfer transistor. The transfer transistor is on the first semiconductor layer 30, which comprises a source doped zone 307, a drain doped zone 306, a poly gate 305, and gate oxide layer 309, but the other MOS transistors in the pixel-readout circuit and external circuit for the image sensor are on the second semiconductor layer 50. A MOS transistor 303 is shown as an example in FIG. 6.

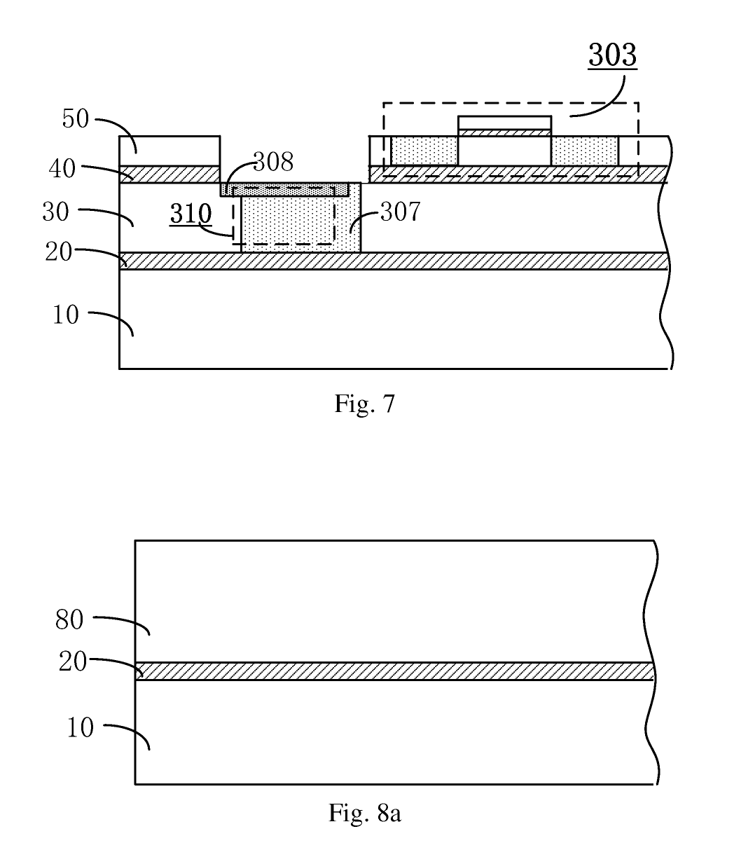

As an optional embodiment illustrated in FIG. 7, the thickness of the first semiconductor layer 30 is 3 μm-5 μm, and the thickness of the second semiconductor layer 50 is 200 nm-250 nm. The pixel-readout circuit is the 3T type CMOS pixel-readout circuit. The photodiode 310 with the PN junction is on the first semiconductor layer 30, and the pixel-readout circuit is on the second semiconductor layer 50. The MOS transistor 303 is shown as an example in FIG. 7.

As another optional embodiment, the thickness of the first semiconductor layer 30 is 100 nm-300 nm; the thickness of the second semiconductor layer 50 is 300 nm-10 μm; a photo sensor is on the second semiconductor layer 50; and the pixel-readout circuit is on the first semiconductor layer 30 in the provided semiconductor substrate.

Description for first method of fabricating the image sensor in the present invention is illustrated as followed.

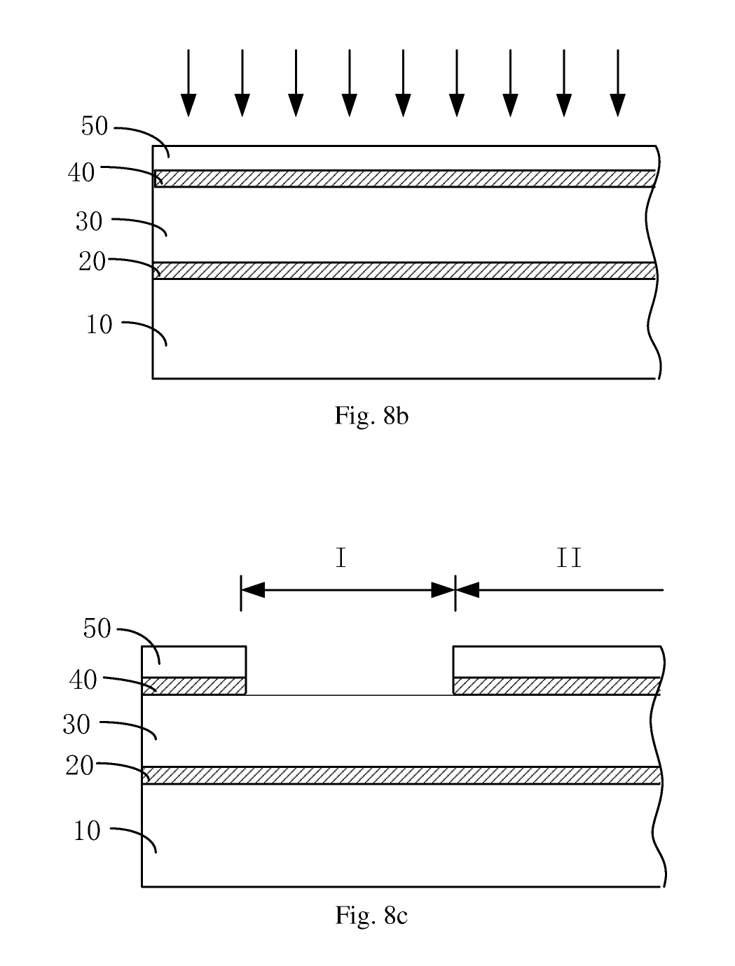

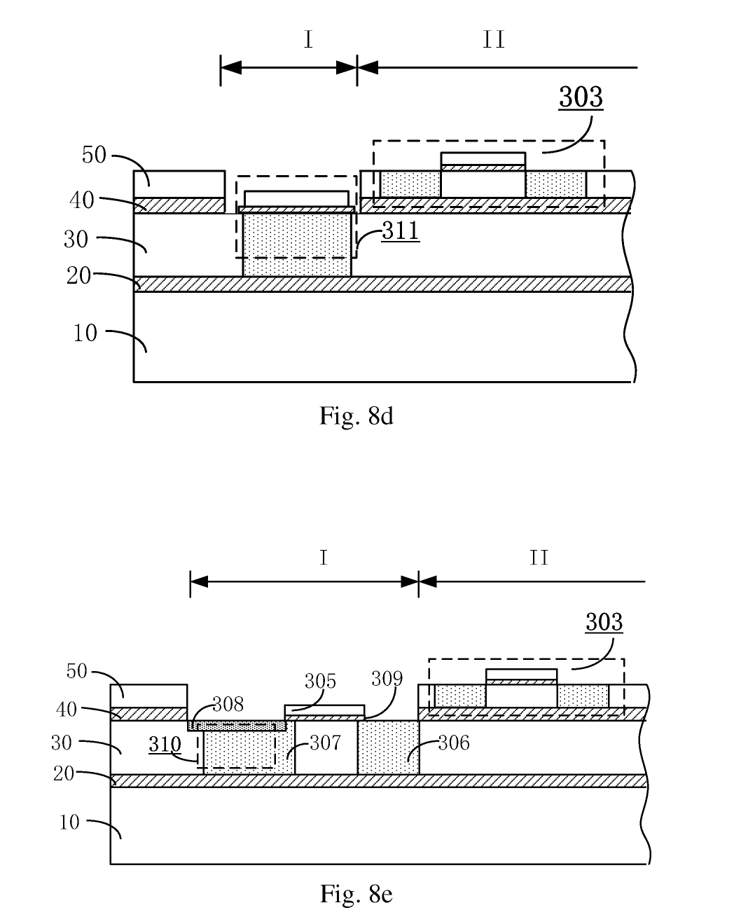

Referring to FIGS. 8a to 8e, the first method of fabricating the image sensor in the present invention comprises the following steps at least:

Step 1: providing a semiconductor substrate with the first insulating buried layer 20, wherein the first insulating buried layer 20 divides the semiconductor substrate into the supporting substrate 10 and a top semiconductor layer 80, as illustrated in FIG. 8a.

Step 2: fabricating the second insulating buried layer 40 in the top semiconductor layer 80, to electrically isolate the top semiconductor layer 80 to the first semiconductor layer 30 and the second semiconductor layer 50, wherein the first semiconductor layer 30 and the second semiconductor layer 50 have different thicknesses, as illustrated in FIG. 8b.

Step 3: defining two zones as zone I and zone II on the surface of the second semiconductor layer 50, wherein a window in the zone I is fabricated by etching to expose surface of the first semiconductor layer 30, as illustrated in FIG. 8c.

Step 4: fabricating a photosensitive component and a pixel-readout circuit in the thicker and thinner semiconductor layers respectively, as illustrated in FIG. 8d or 8e.

In the method of fabricating mentioned above:

In step 1 illustrated in FIG. 8a, the provided semiconductor substrate comprises the supporting substrate 10, the first insulating buried layer 20, and the top semiconductor layer 80, wherein the supporting substrate 10 may be silicon substrate or sapphire, and also be other semiconductor materials such as germanium or silicon-germanium; the first insulating buried layer 20 is one of silica, silicon nitride, and silicon oxide and nitride, and also can be stack structure consisting by them, to realize the electrical isolation between the top semiconductor layer 80 and the supporting substrate 10; the top semiconductor layer 80 is single crystal silicon, or strain silicon or silicon germanium, and also may be other semiconductor material using for fabricating semiconductor components.

As the best embodiment, the supporting substrate 10 is silicon substrate; the first insulating buried layer 20 is silica; the top semiconductor layer 80 is single crystal silicon with thickness of 0.5 μm to 10 μm.

In step 2 illustrate in FIG. 8b, the second insulating buried layer 40 is fabricated by an ion implantation. An ion implantation process is to control ions injected into inner of a semiconductor layer in vacuum by accelerating ions in an electrical filed and adjust moving direction in a magnetic field, in order to fabricate a implantation layer with some special characters in selected zone. For example, if the top semiconductor layer is single crystal silicon, oxygen ions, nitrogen ions or mixed ions by both of them may be selected as the implantation of ions, and an energy rage of the ion implantation is 500 KeV to 1800 KeV. Preferably, oxygen ions are selected to fabricate the second insulating buried layer 40 with thickness of 10 nm-200 nm in this step and an annealing process is introduced after finishing the implantation process.

As the best embodiment, thickness of the initial top semiconductor layer 80 is 2.2 μm-5.5 μm. After applying this step, the thickness of the second insulating buried layer 40 is 50 nm-150 nm. The first semiconductor layer 30 is thicker than the second semiconductor layer 50. The thickness of the first semiconductor layer 30 is 2 μm-5 μm, and the thickness of the second semiconductor layer 50 is 150 nm-250 nm.

As an optional embodiment, thickness of the initial top semiconductor layer 80 is 0.5 μm-2 μm. After applying this step, the thickness of the second insulating buried layer 40 is 100 nm-200 nm, and the thickness of the first semiconductor layer 30 is 100 nm-300 nm. In this embodiment, an epitaxy step on a surface of the second semiconductor layer 50 is comprised after fabricating the second insulating buried layer 40 in the step 2. The epitaxy process thickens the second semiconductor layer 50 to 0.3 μm-10 μm. The second semiconductor layer 50 is thicker than the first semiconductor layer 30.

In step 3 illustrated in FIG. 8c, two zones as zone I and zone II are defined on the surface of the second semiconductor layer 50 by lithographing with photoresist as mask, and then the second semiconductor layer 50 and the second insulating buried layer 40 are removed subsequently to expose the surface of the first semiconductor layer 30.

In this step, the photoresist may be positive or negative, and other materials may be selected as the mask too; and ICP/RID etching process may be used for removing the second semiconductor layer 50 and the second insulating buried layer 40.

In step 4, as a preferable embodiment, the first semiconductor layer 30 is thicker than the second semiconductor layer 50; the photosensitive components are fabricated on the first semiconductor layer 30 and the pixel-readout circuit is fabricated on the second semiconductor layer 50. In this embodiment, the zone I is the zone for the photosensitive components, and the zone II is the zone for the pixel-readout circuit. Preferably, an ion implantation process is used for fabricating these doping zones.

As a preferable embodiment illustrated in FIG. 8d, the photosensitive components is a photogate-like structure, and the pixel-readout circuit is the 3T type CMOS pixel-readout circuit. A doped zone and a gate are fabricated in the first semiconductor layer 30 of the zone I to finish a photogate structure 311 using as photosensitive component and generating electron-hole pairs; the pixel-readout circuit is fabricated in the second semiconductor layer 50 of the zone II, as the MOS transistor 303 illustrated in FIG. 8d. In this step, other external circuit for the image sensor is also fabricated on the second semiconductor layer 50.

As an optional embodiment illustrated in FIG. 8e, the photosensitive component is a photodiode with a PN junction, the pixel-readout circuit is the 4T type CMOS pixel-readout circuit. In this embodiment, the N doped zone 307 and the P doped zone 308 are fabricated in the first semiconductor layer 30 of the zone Ito finish the photodiode 310 with the PN junction. The source doped zone of the transfer transistor in the 4T type CMOS pixel-readout circuit is the N doped zone 307 of the photodiode with the PN junction, and the drain doped zone 306, poly silicon gate 305, and gate oxide layer 309 are fabricated on the first semiconductor layer 30 of the zone I. The other transistors and external circuit related to the image sensor in the 4T type CMOS pixel-readout circuit are fabricated on the second semiconductor layer 50 of the zone II. The MOS transistor 303 is shown as an example in FIG. 8e.

As another embodiment, the thickness of the first semiconductor layer 30 is less than that of the second semiconductor layer 50. The photosensitive devices are fabricated on the second semiconductor layer, and the pixel-readout circuit is fabricated on the first semiconductor layer 30. In this embodiment, the zone I is for the pixel-readout circuit, and the zone II is for the photosensitive devices. The structure and fabricating method are similar to above, and omitted.

It needs to be mentioned that, the method above also comprises fabricating sidewall for the gate of the MOS transistors, fabricating the isolation layer for the neighboring devices (such as STI isolation) and metal connection between devices, and other steps such as doping, device isolating, lithographing, etching, surface treating, and so on. The above steps are prior arts for skilled person in this technology field, so the further description is omitted.

In the image sensor of the present invention, the photosensitive component is in thicker semiconductor layer, to obtain a deeper depletion zone in the PN junction, and have a higher light absorption rate. In addition, the pixel-readout circuit is in a thinner semiconductor layer to make the MOS transistor depleted, so the circuit has advantages of high speed, low energy consumption, and anti latch-up. Moreover, the photosensitive components and the pixel-readout circuit of the image sensor are electrically isolated by the insulating buried layer to the supporting substrate, to enhance their ability of anti high energy particles radiation.

The present invention also provides second method of fabricating the image sensor. Firstly, providing a first semiconductor substrate and a second semiconductor substrate, wherein the first semiconductor substrate comprises: a first supporting substrate, a first insulating buried layer in the first supporting substrate, and a first top semiconductor layer on a surface of the first insulating buried layer; fabricating a second insulating buried layer on the surface of the first semiconductor substrate or the second semiconductor substrate, and bonding the first semiconductor substrate and the second semiconductor substrate, with the second insulating buried layer between the first top semiconductor layer and the second semiconductor substrate; thinning the second semiconductor substrate to fabricate the second top semiconductor layer with different thicknesses to the first top semiconductor layer, wherein the thicker one in the first top semiconductor layer and the second top semiconductor layer is a thick film layer and the other one is a thin film layer on the contrary; defining zone I and zone II on a surface of the second top semiconductor layer, and opening a window in the zone I until the surface of the first top semiconductor layer is exposed; and fabricating photosensitive components and pixel-readout circuit in the zone I and zone II, wherein the photosensitive components are fabricated in the thick film layer and neighboring devices are isolated, to finish fabricating the image sensor.

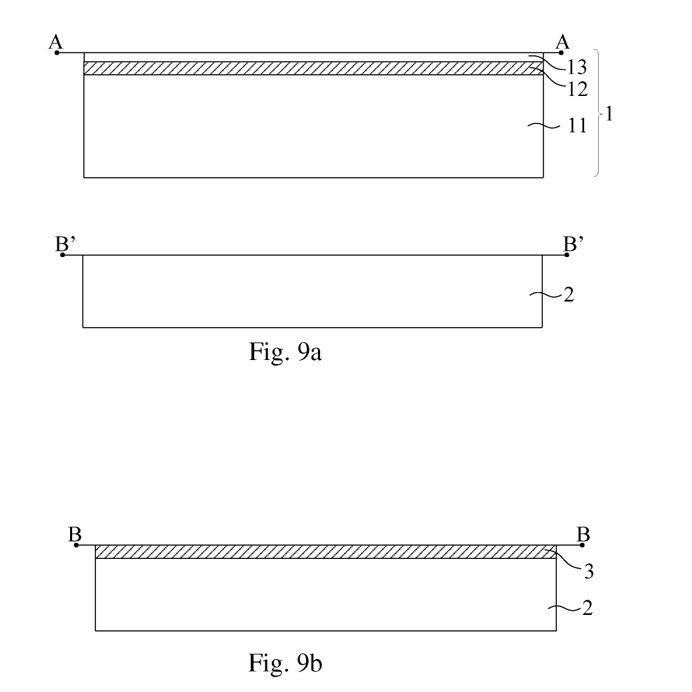

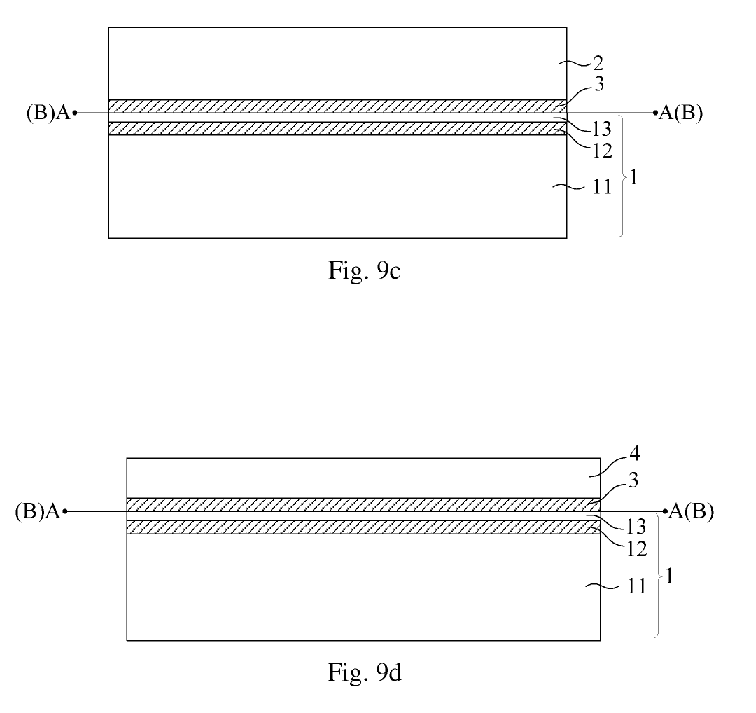

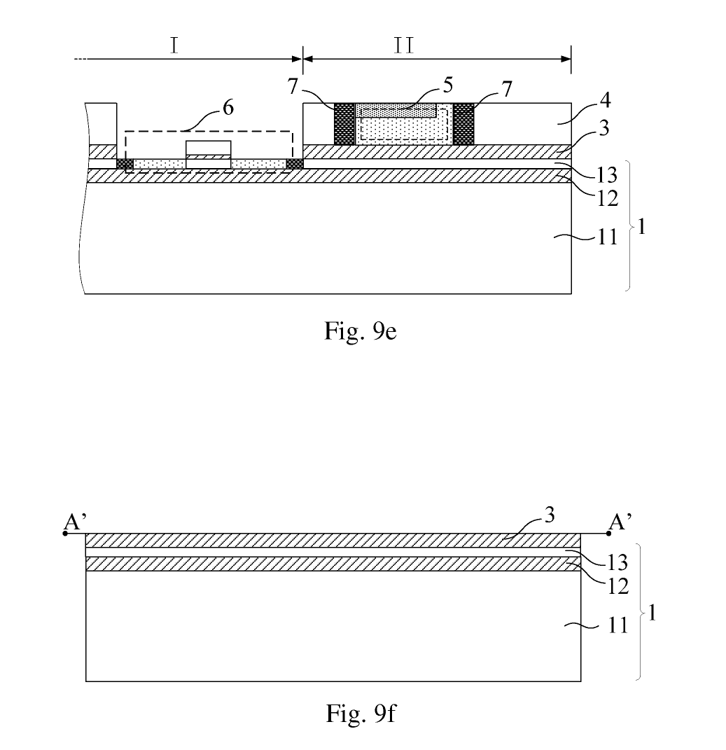

Please refer to FIG. 9a to FIG. 12. It needs to be mentioned that, figures mentioned in examples below only illustrate basic ideas of the present invention by diagramming. So, not real numbers, shapes or sizes, but the components in the present invention are illustrated in the figures. The real shape, number and ratio can be changed and the components' distribution may be more complex.

### Example 1

As illustrated in FIGS. 9a to 9f, the present invention provides a method of fabricating an image sensor, which at least comprises the following steps:

As illustrated in FIG. 9a, the first semiconductor substrate 1 and the second semiconductor substrate 2 are provided in the step 1), wherein the first semiconductor substrate 1 comprises: a first supporting substrate 11, a first insulating buried layer 12 in the first supporting substrate 11, and a first top semiconductor layer 13 on a surface of the first insulating buried layer 12.

In this example, a material of the first top semiconductor layer 13 is the one used for fabricating semiconductor components, at least comprises any one of silicon, strained silicon, germanium, and silicon germanium; the first insulating buried layer 12 is a single layer or multi layer structure, wherein material of each layer in the single layer or multi layer structure is any one of silicon oxide, nitride oxide, and silicon nitride and oxide; the first supporting substrate 11 is a common semiconductor substrate (at least comprises a silicon substrate or a sapphire substrate); the second semiconductor substrate 2 is a common semiconductor substrate (at least comprises a silicon substrate or a sapphire substrate) or a semiconductor substrate with an insulating buried layer (at least comprises a silicon-on-insulator or a germanium-on-insulator, and a silicon or a sapphire for its substrate material). In particular, in example 1, the first top semiconductor layer 13 is single crystal silicon; the first insulating buried layer 12 is silicon oxide with a single layer; the first supporting substrate 11 is a silicon supporting substrate; and the second semiconductor substrate 2 is a silicon substrate. A surface of the second semiconductor substrate 2 is illustrated as B′-B′ (as illustrated in FIG. 9a).

It needs to be mentioned that, the first top semiconductor layer 13 is a thin film layer or thick film layer, wherein the thickness of the thin film is 0.1 μm-0.3 μm and the thickness of the thick film is 0.3 μm-10 μm. In the example 1, the first top semiconductor layer 13 is thin silicon film with thickness of 0.1 μm-0.3 μm. A surface of the first top semiconductor layer 13 in the first semiconductor substrate 1 is illustrated as A-A surface. (as illustrated in FIG. 9a). Then execute step 2).

As illustrated in FIG. 9b, the second insulating buried layer 3 is fabricated on the surface of the second semiconductor substrate 2 (B-B surface in FIG. 9b is surface of the second insulating buried layer 3 in the step 2). The method of fabricating the second insulating buried layer 3 comprises: depositing material for the second insulating buried layer on the surface of the second semiconductor substrate 2, to fabricate the second insulating buried layer 3, using chemical vapor deposition or physical vapor deposition process; or thermal oxidizing the second semiconductor substrate 2 to fabricate oxide layer on the surface used as the second insulating buried layer 3. In the example 1, thermal oxidizing process is used to fabricate the oxide layer on the surface of the second semiconductor substrate 2 as the second insulating buried layer 3.

It needs to be mentioned that, in another example, the second insulating buried layer 3 is fabricated on the surface of the first semiconductor substrate 1 in the step 2) (A′-A′ surface in FIG. 9f is surface of the second insulating buried layer 3). The method of fabricating the second insulating buried layer 3 comprises: depositing material for the second insulating buried layer on the surface of the first semiconductor substrate 1, to fabricate the second insulating buried layer 3, using chemical vapor deposition or physical vapor deposition process; or thermal oxidizing the first semiconductor substrate 1 to fabricate oxide layer on the surface used as the second insulating buried layer 3.

It needs to be mentioned that, the second insulating buried layer 3 is a single layer or multi layer structure, wherein material of each layer in the single layer or multi layer structure is any one in silicon oxide, nitride oxide, and silicon nitride and oxide. In the present example, the second insulating buried layer 3 is silicon oxide with the single layer. Then execute step 3).

As illustrated in FIG. 9c, the step 3) is aligning bonding the second insulating buried layer 3 and the first top semiconductor layer 13 in the first semiconductor substrate 1 using common bonding technology, after fabricating the second insulating buried layer 3 on the surface of the second semiconductor substrate 2. In FIG. 9c, the common bonding technology (Si—SiO₂ bonding) is used in this embodiment, to aligning bond the surface of the first top semiconductor layer 13 of the first semiconductor substrate 1 marked as the A-A surface (illustrated in FIG. 9a) and the surface of the second insulating buried layer 3 marked as B-B surface (illustrated in FIG. 9b), and then the second insulating buried layer 3 is set between the first top semiconductor layer 13 and the second semiconductor substrate 2. It needs to be mentioned that, in another embodiment, the common bonding technology is used to aligning bond the surface of the second semiconductor substrate 2 and the second insulating buried layer 3 after fabricating the second insulating buried layer 3 on the surface of the first semiconductor substrate 1 in the step 3) above. That is to say, the common bonding technology is used to aligning bond the surface of the second semiconductor substrate 2 marked as the B′-B′ surface (illustrated in FIG. 9a) and the surface of the second insulating buried layer 3 marked as A′-A′ surface (illustrated in FIG. 9f), and then the second insulating buried layer 3 is set between the first top semiconductor layer 13 and the second semiconductor substrate 2. Then execute step 4).

As illustrated in FIG. 9d, the second semiconductor substrate 2 is thinned and then the second top semiconductor layer 4 is fabricated in the step 4). The second top semiconductor layer 4 may be a thin film layer or thick film layer, wherein the thickness of the thin film layer is 0.1 μm-0.3 μm and the thickness of the thick film layer is 0.3 μm-10 μm. Particularly, in the example 1, the second top semiconductor layer 4 is the thick film layer with thickness of 0.3 μm-10 μm, for the thin film layer with thickness of 0.1 μm-0.3 μm is selected as the first top semiconductor layer 13, wherein the optimized thickness for the second top semiconductor layer 4 is 2 μm-3 μm. It needs to be mentioned that, the thin film layer with thickness of 0.1 μm-0.3 μm is selected as the second top semiconductor layer 4, for the first top semiconductor layer 13 is the thick film layer with thickness of 0.3 μm-10 μm in another embodiment.

As illustrated in FIG. 9d, the first top semiconductor layer 13 is the thin silicon film layer with thickness of 0.1 μm-0.3 μm; the second semiconductor substrate 2 is silicon substrate, and the second top semiconductor layer 4 is the thick silicon film layer with thickness of 0.3 μm-10 μm (optimized thickness is 2 μm-3 μm). The thinning process comprises etching process ahead and planarization process subsequently in the step 4). The second semiconductor substrate 2 (silicon substrate) is etched and planned. Particularly, chemical and mechanical polishing process is used in the planarization process, to fabricate the second top semiconductor layer 4, wherein the second top semiconductor layer 4 is the thick silicon film layer with thickness of 0.3 μm-10 μm (optimized thickness is 2 μm-3 μm). Then execute step 5).

As illustrated in FIG. 9e, two zones as zone I and zone II are defined on the surface of the second top semiconductor layer 4, and a window in the zone I is fabricated by etching to expose surface of the first top semiconductor layer 13 in the step 5). Common lithography and etch (including ICP or IRE at least) processes are used to fabricate the window in the zone I in this step. In the example 1, Common lithography, ICP, and etch processes are used to fabricate the window in the zone I of the surface of the second top semiconductor layer 4, to expose the surface of the first top semiconductor layer 13. Then execute step 6).

As illustrated in FIG. 9e, photosensitive components 5 and pixel-readout circuit 6 are fabricated in the zone I and zone II. The photosensitive components 5 are fabricated in the thick film layer, and STI or dielectric isolation are used to fabricate the isolation 7 between the components, to fabricate the image sensor.

It needs to be mentioned that, the photosensitive components 5 comprise a photodiode (a photodiode with a PN junction or PIN junction) or a photo-electric gate at least, and are fabricated in the thick film layer; the pixel-readout circuit 6 is the 3T, 4T or other type readout circuit with MOS transistors; the 3T pixel-readout circuit comprises a reset transistor, an amplified transistor and a row select transistor fabricated in the thin film layer; the 4T pixel-readout circuit comprises a transfer transistor, a reset transistor, an amplified transistor and a row select transistor, wherein the transfer transistor is fabricated in the thick film layer and the reset transistor, amplified transistor and row select transistor are fabricated in the thin film layer. Particularly, as illustrated in FIG. 9e, the photosensitive components 5 is a photodiode with a PN junction, and the pixel-readout circuit 6 is the 3T type (only one transistor is illustrated in the figure) in the example 1.

The first top semiconductor layer 13 is a silicon thin film layer with thickness of 0.1 μm-0.3 μm, and the second top semiconductor layer 4 is a silicon thick film layer with thickness of 0.3 μm-10 μm (optimized thickness is 2 μm-3 μm) in the example 1. The window is fabricated to expose the surface of the first top semiconductor layer 13 in the zone I, and the zone II is in the second top semiconductor layer 4, as illustrated in FIG. 9e. The photosensitive components 5 is a photodiode with a PN junction fabricated in the zone II of the second top semiconductor layer 4 as the thick film layer. The pixel-readout circuit 6 is the 3T type (only one transistor is illustrated in the figure) fabricated in the zone I of the first top semiconductor layer 13 as the thin film layer. The isolations 7 between the components are fabricated with dielectric isolation, to fabricate the image sensor.

The image sensor in the present invention has good anti-radiation ability, and the photosensitive zone in the image sensor have higher photo absorbing rate. The circuit for the image sensor is high speed, low energy consumption, avoiding latch-up effect. So the image sensor has good semiconductor characterizations.

### Example 2

As illustrated in 10a to 10f, the present invention provides a method of fabricating an image sensor, which comprises the following steps at least:

As illustrated in 10a, the first semiconductor substrate 1 and second semiconductor substrate 2, is provided in the step 1), wherein the first semiconductor substrate 1 comprises: a first supporting substrate 11, a first insulating buried layer 12 in the first supporting substrate 11, and a first top semiconductor layer 13 on a surface of the first insulating buried layer12.

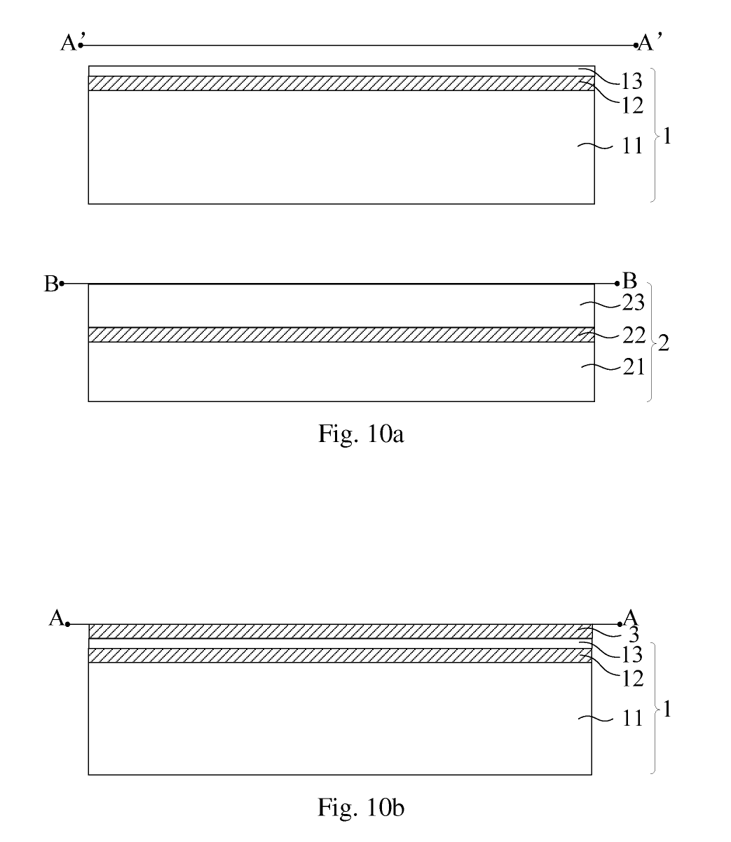

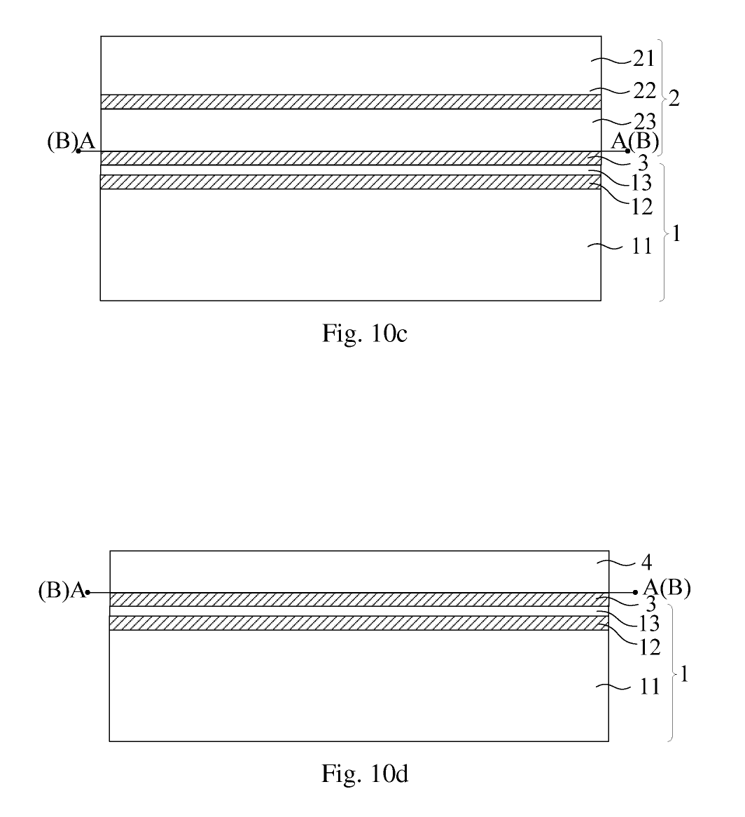

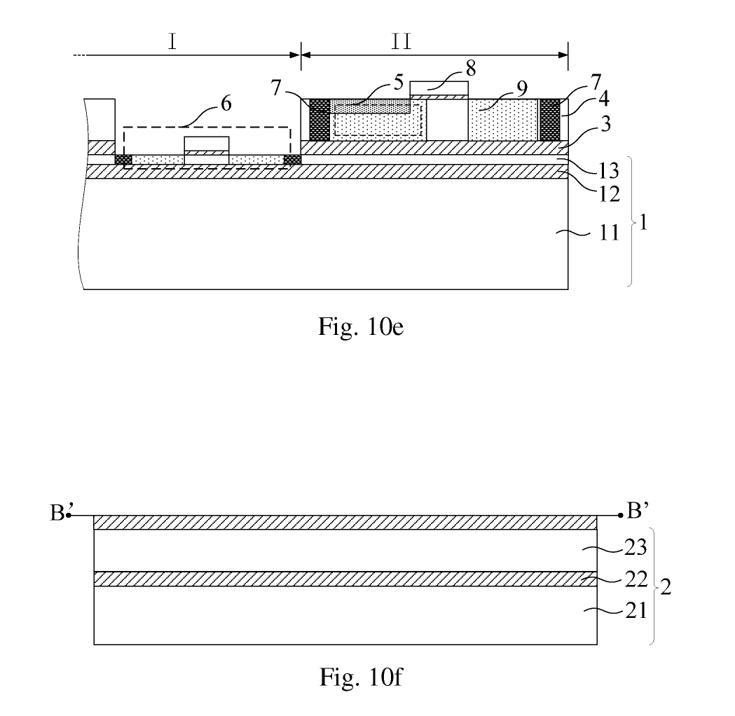

In this example, a material of the first top semiconductor layer 13 is the one used for fabricating semiconductor components, at least comprises any one of silicon, strained silicon, germanium, and silicon germanium; the first insulating buried layer 12 is a single layer or multi layer structure, wherein a material of each layer in the single layer or multi layer structure is any one in silicon oxide, nitride oxide, and silicon nitride and oxide; the first supporting substrate 11 is a common semiconductor substrate (at least comprises a silicon substrate or a sapphire substrate); the second semiconductor substrate 2 is a common semiconductor substrate (at least comprises a silicon substrate or a sapphire substrate) or a semiconductor substrate with an insulating buried layer (at least comprises a silicon-on-insulator or a germanium-on-insulator, and a silicon or a sapphire for its substrate material). In particular, in the example 2, the first top semiconductor layer 13 is single crystal silicon; the first insulating buried layer 12 is silicon nitride with the single layer, the first supporting substrate 11 is sapphire supporting substrate; and the second semiconductor substrate 2 is semiconductor substrate with insulating buried layer, and optimized choice is SOI substrate comprises: a supporting substrate 21 in the second semiconductor substrate 2, an insulating buried layer 22 in the second semiconductor substrate 2 on a surface of the supporting substrate 21, and top semiconductor layer 23 in the second semiconductor substrate 2 on a surface of the insulating buried layer 22, wherein the supporting substrate is a sapphire substrate, the insulating buried layer 22 is silicon oxide and the top semiconductor layer 23 is silicon. A surface of the second semiconductor substrate 2 is illustrated as B′-B′ (as illustrated in FIG. 10a).

It needs to be mentioned that, the first top semiconductor layer 13 is a thin film layer or thick film layer, wherein the thickness of the thin film is 0.1 μm-0.3 μm and the thickness of the thick film is 0.3 μm-10 μm. In the example 2, the first top semiconductor layer 13 is thin silicon film with thickness of 0.1 μm-0.3 μm, wherein the optimized thickness of the first top semiconductor layer 13 is 0.15 μm-0.2 μm. A surface of the first top semiconductor layer 13 in the first semiconductor substrate 1 is illustrated as A-A surface (as illustrated in FIG. 10a).

It needs to be mentioned that, the second semiconductor substrate 2 is a semiconductor substrate with an insulating buried layer. In this example, the top semiconductor layer 23 in the second semiconductor substrate 2 is a thick film layer or thin film layer, wherein the thickness of the thin film layer is 0.1 μm-0.3 μm, and the thickness of the thick film layer is 0.3 μm-10 μm. In the example 2, the top semiconductor layer 23 in the second semiconductor substrate 2 is a thick film layer with thickness of 0.3 μm-10 μm, for the first top semiconductor layer 13 is the thin film layer with thickness of 0.1 μm-0.3 μm (an optimized thickness is 0.15 μm-0.2 μm), wherein the optimized thickness of the top semiconductor layer 23 in the second semiconductor substrate 2 is 3 μm-5 μm. In another example, if the first top semiconductor layer 13 is the thick film layer with thickness of 0.3 μm-10 μm, the top semiconductor layer 23 in the second semiconductor substrate 2 is a thin film layer with thickness of 0.1 μm-0.3 μm. Then execute step 2).

As illustrated in FIG. 10b, the second insulating buried layer 3 is fabricated on the surface of the first semiconductor substrate 1 in the step 2) (A-A surface in FIG. 10b is surface of the second insulating buried layer 3). The method of fabricating the second insulating buried layer 3 comprises: depositing material for the second insulating buried layer on the surface of the first semiconductor substrate 1, to fabricate the second insulating buried layer 3, using chemical vapor deposition or physical vapor deposition process; or thermal oxidizing the first semiconductor substrate 1 to fabricate oxide layer on the surface used as the second insulating buried layer 3. In the example 2, the chemical vapor deposition process is used to fabricate material for the second insulating buried layer on the surface of the first semiconductor substrate 1 as the second insulating buried layer 3.

It needs to be mentioned that, in another example, the second insulating buried layer 3 is fabricated on the surface of the second semiconductor substrate 2 in the step 2) (B′-B′ surface in FIG. 10f is surface of the second insulating buried layer 3). The method of fabricating the second insulating buried layer 3 comprises: depositing material for the second insulating buried layer on the surface of the second semiconductor substrate 2, to fabricate the second insulating buried layer 3, using chemical vapor deposition or physical vapor deposition process; or thermal oxidizing the second semiconductor substrate 2 to fabricate oxide layer on the surface used as the second insulating buried layer 3.

It needs to be mentioned that, the second insulating buried layer 3 is a single layer or multi layer structure, wherein material of each layer in the single layer or multi layer structure is any one in silicon oxide, nitride oxide, and silicon nitride and oxide. In the present example, the second insulating buried layer 3 is silicon nitride with the single layer. Then execute step 3).

As illustrated in FIG. 10c, the second insulating buried layer 3 is aligning bonded to the second semiconductor substrate 2 using a common bonding technology in the step 3), after fabricating the second insulating buried layer 3 on the surface of the first semiconductor substrate 1. In FIG. 10c, the common bonding technology is used in this embodiment, to aligning bond the surface of the second semiconductor substrate 2 marked as the B-B surface (illustrated in FIG. 10a) and the surface of the second insulating buried layer 3 marked as A-A surface (illustrated in FIG. 10b), and then the second insulating buried layer 3 is set between the first top semiconductor layer 13 and the second semiconductor substrate 2. It needs to be mentioned that, in another embodiment, the common bonding technology is used to aligning bond the first top semiconductor layer 13 in the first semiconductor substrate 1 and the second insulating buried layer 3 after fabricating the second insulating buried layer 3 on the surface of the second semiconductor substrate 2 in the step 3) above. That is to say, the common bonding technology is used to aligning bond the surface of the first top semiconductor layer 13 in the first semiconductor substrate 1 marked as the A′-A′ surface (illustrated in FIG. 10a) and the surface of the second insulating buried layer 3 marked as B′-B′ surface (illustrated in FIG. 10f), and then the second insulating buried layer 3 is set between the first top semiconductor layer 13 and the second semiconductor substrate 2. Then execute step 4).

As illustrated in FIG. 10d, the second semiconductor substrate 2 is thinned and then the second top semiconductor layer 4 is fabricated in the step 4). The second top semiconductor layer 4 may be a thin film layer or thick film layer, wherein the thickness of the thin film layer is 0.1 μm-0.3 μm and the thickness of the thick film layer is 0.3 μm-10 μm. In the example 2, the second top semiconductor layer 4 is a thick film layer with thickness of 0.3 μm-10 μm, for the thin film layer with thickness of 0.1 μm-0.3 μm (optimized thickness is 0.15 μm-0.2 μm) is selected as the first top semiconductor layer 13. It needs to be mentioned that, the thin film layer with thickness of 0.1 μm-0.3 μm is selected as the second top semiconductor layer 4, for the first top semiconductor layer 13 is a thick film layer with thickness of 0.3 μm-10 μm in another embodiment.

As illustrated in FIG. 10d, the first top semiconductor layer 13 is the thin film layer with thickness of 0.1 μm-0.3 μm; the second semiconductor substrate 2 is semiconductor substrate with insulating buried layer, and optimized one is silicon-on-insulator (SOI, the substrate material is sapphire). The top semiconductor layer 23 in the second semiconductor substrate 2 is the thick film layer with thickness of 0.3 μm-10 μm (optimized thickness is 3 μm-5 μm), and the second top semiconductor layer 4 is a thick film layer with thickness of 0.3 μm-10 μm. Thereof, the thinning process in the step 4) comprises: etching the supporting substrate 21 in the second semiconductor substrate 2, then etching the insulating buried layer 22 in the second semiconductor substrate 2, and remaining the top semiconductor layer 23 of the second semiconductor substrate 2, to fabricate the second top semiconductor layer 4. Wherein, the top semiconductor layer 23 of the second semiconductor substrate 2 is the second top semiconductor layer 4, and is thick silicon film layer with thickness of 0.3 μm-10 μm (optimized thickness is 3 μm-5 μm). Furthermore, the top semiconductor layer 23 of the second semiconductor substrate 2 is planned after etching the supporting substrate 21 and the insulating buried layer 22 in the second semiconductor substrate 2 in another embodiment. Particularly, chemical and mechanical polishing process is used in the planarization process to fabricate the second top semiconductor layer 4, wherein the second top semiconductor layer 4 is the thick silicon film layer with thickness of 0.3 μm-10 μm (optimized thickness is 3 μm˜5 μm). Then execute step 5).

As illustrated in FIG. 10e, two zones as zone I and zone II are defined on the surface of the second top semiconductor layer 4, and a window in the zone I is fabricated by etching to expose surface of the first top semiconductor layer 13 in the step 5). Wherein, common lithography and etch (including ICP or IRE at least) processes are used to fabricate the window in the zone I in this step. In the example 2, common lithography, ICP, and etch processes are used to fabricate the window in the zone I of the surface of the second top semiconductor layer 4, to expose the surface of the first top semiconductor layer 13. Then execute step 6).

As illustrated in FIG. 10e, photosensitive components 5 and the pixel-readout circuit 6 are fabricated in the zone I and zone II. The photosensitive components 5 are fabricated in the thick film layer, and STI or dielectric isolation are used to fabricate the isolation 7 between the components, to fabricate the image sensor.

It needs to be mentioned that, the photosensitive components 5 comprise a photodiode (a photodiode with a PN junction or PIN junction) or a photo-electric gate at least, and are fabricated in the thick film layer; the pixel-readout circuit 6 is the 3T, 4T or other type readout circuit with MOS transistors; the 3T pixel-readout circuit comprises a reset transistor, an amplified transistor and a row select transistor fabricated in the thin film layer; the 4T pixel-readout circuit comprises a transfer transistor, a reset transistor, an amplified transistor and a row select transistor, wherein the transfer transistor is fabricated in the thick film layer and the reset transistor, amplified transistor and row select transistor are fabricated in the thin film layer. Particularly, as illustrated in FIG. 10e, the photosensitive components 5 is a photodiode with a PN junction, and the pixel-readout circuit 6 is the 4T type, wherein the reset transistor, amplified transistor and row select transistor are illustrated by only one transistor (see FIG. 10e) in the example 2. The zone for fabricating the transfer transistor 8, floating diffusion zone 9 in the 4T pixel-readout circuit is different to that for fabricating the reset transistor, amplified transistor and row select transistor.

The first top semiconductor layer 13 is thin silicon film layer with thickness of 0.1 μm-0.3 μm (optimized thickness is 0.15 μm-0.2 μm), and the second top semiconductor layer 2 is silicon-on-insulator (SOI, the substrate material is sapphire). The second top semiconductor layer 4 (as the top semiconductor layer 23 of the second semiconductor substrate 2) is thick silicon film layer with thickness of 0.3 μm-10 μm (optimized thickness is 3 μm-5 μm) in the example 2. The window is fabricated to expose the surface of the first top semiconductor layer 13 in the zone I, and the zone II is in the second top semiconductor layer 4, as illustrated in FIG. 10e. The photosensitive components 5 is a photodiode with a PN junction fabricated the zone II of the second top semiconductor layer 4 as the thick film layer. The pixel-readout circuit 6 is the 4T type, wherein the reset transistor, amplified transistor and row select transistor illustrated by only one transistor are fabricated in the zone I of the first top semiconductor layer 13 as the thin film layer. The transfer transistor 8, floating diffusion zone 9 in the 4T pixel-readout circuit are fabricated in the zone II of the second top semiconductor layer 4 as the thick film layer. The isolations 7 between the components are fabricated with dielectric isolation, to fabricate the image sensor.

The image sensor in the present invention has good anti-radiation ability, and the photosensitive zone in the image sensor have higher photo absorbing rate. The circuit for the image sensor is high speed, low energy consumption, avoiding latch-up effect. So the image sensor has good semiconductor characterizations.

### Example 3

The example 3 basically has the same method to the example 1, and the main difference is as followed: the first top semiconductor layer 13 in the first semiconductor substrate 1 is thin silicon film with thickness of 0.1 μm-0.3 μm, and the second top semiconductor layer 4 is a thick film layer with thickness of 0.3 μm-10 μm (optimized thickness is 2 μm-3 μm) in the example 1; and the first top semiconductor layer 13 in the first semiconductor substrate 1 is thick strained-silicon film layer with thickness of 0.3 μm-10 μm (optimized thickness is 6 μm-8 μm), and the second semiconductor substrate 2 is silicon-on insulator (SOI) in the example 3. The second top semiconductor layer 4 and the top semiconductor layer 23 in the second semiconductor substrate 2 are both thin silicon film layer with thickness of 0.1 μm-0.3 μm.

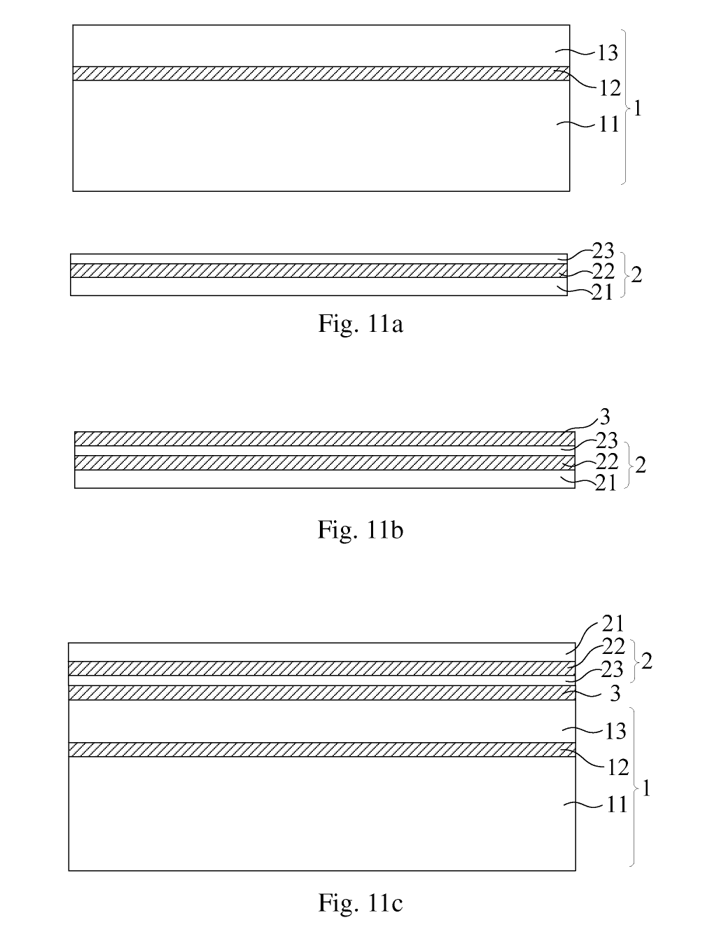

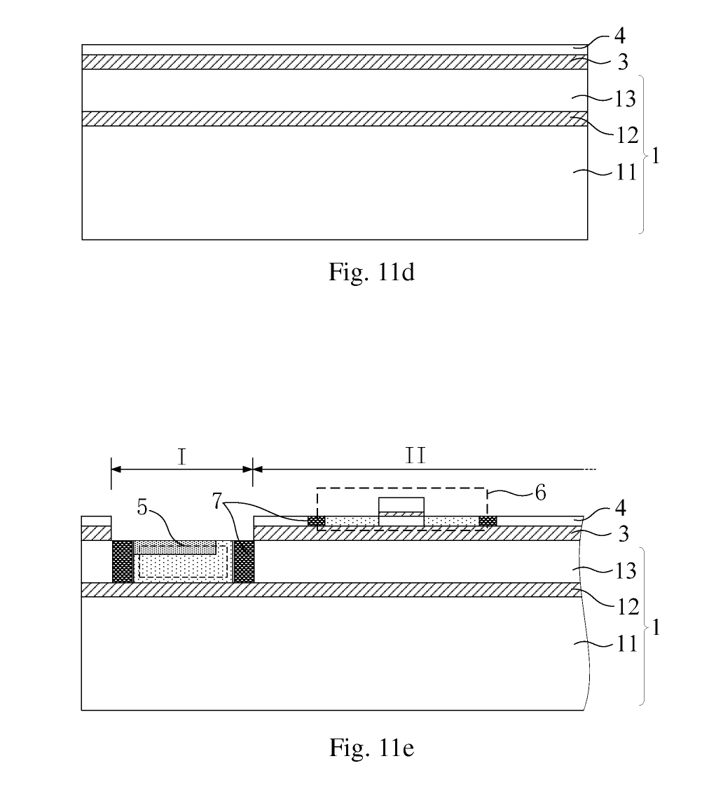

As illustrated in FIG. 11a to 11e, a method of fabricating an image sensor is provided in the present invention, which at least comprises the following steps:

As illustrated in FIG. 11a, the step 1) basically the same step to it in the example 1 is executed, and the difference is:

In the example 3, the first top semiconductor layer 13 in the first semiconductor substrate 1 is thick strained-silicon film layer with thickness of 0.3 μm-10 μm (optimized thickness is 6 μm-8 μm), and the second semiconductor substrate 2 is semiconductor substrate with insulating buried layer. The optimized one is silicon-on insulator (SOI) which comprises: supporting substrate 21 in the second semiconductor substrate 2, the insulating buried layer 22 in the second semiconductor substrate 2 on a surface of the supporting substrate 21, and top semiconductor layer 23 in the second semiconductor substrate 2 on a surface of the insulating buried layer 22, wherein the supporting substrate 21 is silicon substrate, the insulating buried layer 22 is silicon oxide and the top semiconductor layer 23 is silicon. Particularly, the top semiconductor layer 23 in the second semiconductor substrate 2 is thin silicon film layer with thickness of 0.1 μm-0.3 μm.

Then execute the step 2) as illustrated in FIG. 11b. In the example 3, the second insulating buried layer is deposited on the surface of the second semiconductor substrate 2 using physical vapor deposition process, to fabricate the second insulating buried layer 3, and the second insulating buried layer 3 is stack structure with double layers, and material of each layer is selected in silicon nitride, and silicon oxide and nitride.

Then execute the step 3) same to that in the example 1 as illustrated in FIG. 11c. In the example 3, common bonding process is used as aligning bonding the second insulating buried layer 3 and the first top semiconductor layer 13 in the first semiconductor substrate 1. Then execute the step 4).

Then execute the step 4) basically the same to that in the example 1 as illustrated in FIG. 11d, wherein the difference is: the first top semiconductor layer 13 is a thick film layer with thickness of 0.3 μm-10 μm (optimized thickness is 6 μm-8 μm), and the second semiconductor substrate 2 is semiconductor substrate with insulating buried layer. The optimized one is silicon-on insulator (SOI), wherein the top semiconductor layer 23 in the second semiconductor substrate 2 is thin film layer with thickness of 0.1 μm-0.3 μm, and so the second top semiconductor layer 4 is thin film layer with thickness of 0.1 μm-0.3 μm.

It needs to be mentioned that, the same thinning process is used in the example 3 and example 1 in the step 4), which is to etch the supporting substrate 21 in the second semiconductor substrate 2, and then etch the insulating buried layer 22 in the second semiconductor substrate 2, to remain the top semiconductor layer 23 in the second semiconductor substrate 2 as the second top semiconductor layer 4. Wherein the top semiconductor layer 23 in the second semiconductor substrate 2 is the second top semiconductor layer mentioned above made by silicon with the thickness of 0.1 μm-0.3 μm.

Furthermore, in another embodiment, the top semiconductor layer 23 in the second semiconductor substrate 2 is planned after the supporting substrate 21 and the insulating buried layer 22 in the second semiconductor substrate 2 are etched. Particularly, CMP process is used to execute the planarization process, to fabricate the second top semiconductor layer 4, which is a thin film layer with thickness of 0.1 μm-0.3 μm. Then execute the step 5).

Then execute the step 5) as illustrated in FIG. 11e. In the example 3, common lithography, ICP and etching processes are used to open a window on the surface of the second top semiconductor layer 4 in the zone I, to expose the first top semiconductor layer 13. Then execute the step 6).

Then execute the step 6) basically the same to that in the example 1 as illustrated in FIG. 11e, wherein the difference is:

The first top semiconductor layer 13 in the first top semiconductor substrate 1 is thick strained-silicon film layer with thickness of 0.3 μm-10 μm (optimized thickness is 6 μm-8 μm), and the second semiconductor substrate 2 is silicon-on insulator (SOI). The second top semiconductor layer 4 (as the top semiconductor layer 23 in the second semiconductor substrate 2) is thin silicon film layer with thickness of 0.1 μm-0.3 μm. The window is opened in the zone I to expose the surface of the first top semiconductor layer 13. The zone II is in the second top semiconductor layer 4 as illustrated in FIG. 11e. The photosensitive component 5 is a photodiode with a PN junction fabricated on the zone I of the first top semiconductor layer 13 as the thick film. The pixel-readout circuit 6 is the 3T type (only one transistor is illustrated for the pixel-readout circuit) and fabricated on the zone II of the second top semiconductor layer 4 as the thin film.

It needs to be mentioned that, in the step 6), the same parts between the example 3 and example 1 are:

i) The photosensitive component 5 and the pixel-readout circuit 6 are same as illustrated in FIG. 11e. In the example 3, the photosensitive component 5 is photodiode with the PN junction, and the pixel-readout circuit 6 is the 3T type (only one transistor is illustrated for the pixel-readout circuit).

ii) They have the same isolation method as illustrated in FIG. 11e. In the example 3, the isolations 7 between the components are fabricated with dielectric isolation, to fabricate the image sensor.

The image sensor in the present invention has good anti-radiation ability, and the photosensitive zone in the image sensor have higher photo absorbing rate. The circuit for the image sensor is high speed, low energy consumption, avoiding latch-up effect. So the image sensor has good semiconductor characterizations.

### Example 4

As illustrated in 12a to 12f, the present invention provides a method of fabricating an image sensor, which comprises the following steps at least:

As illustrated in 12a, the first semiconductor substrate 1 and second semiconductor substrate 2, are provided in the step 1), wherein the first semiconductor substrate 1 comprises: a first supporting substrate 11, a first insulating buried layer 12 in the first supporting substrate 11, and a first top semiconductor layer 13 on a surface of the first insulating buried layer12.

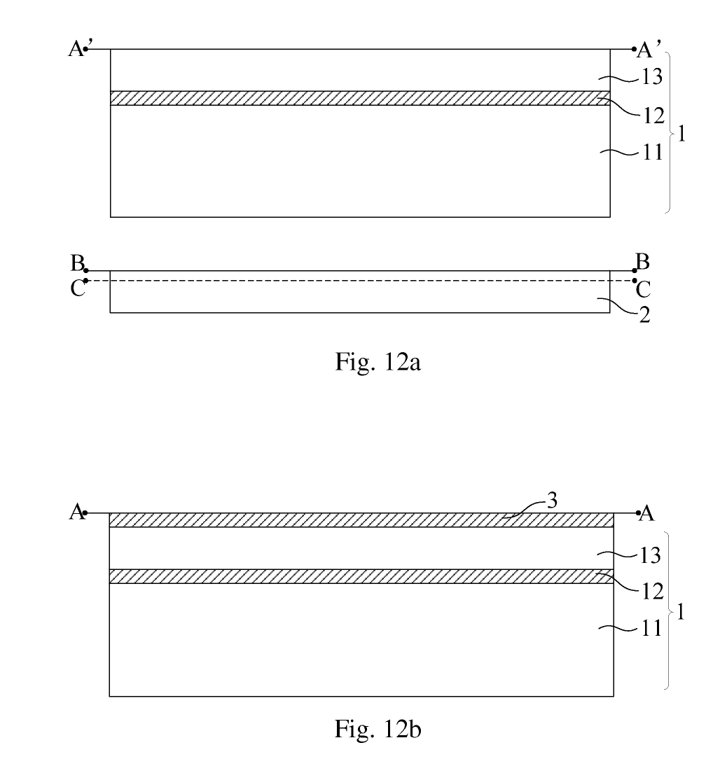

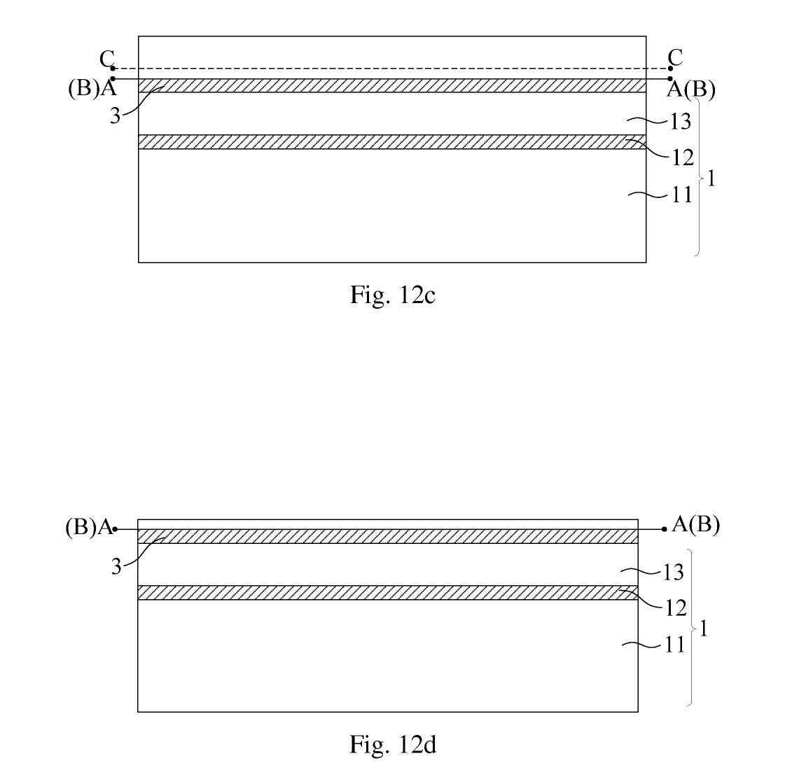

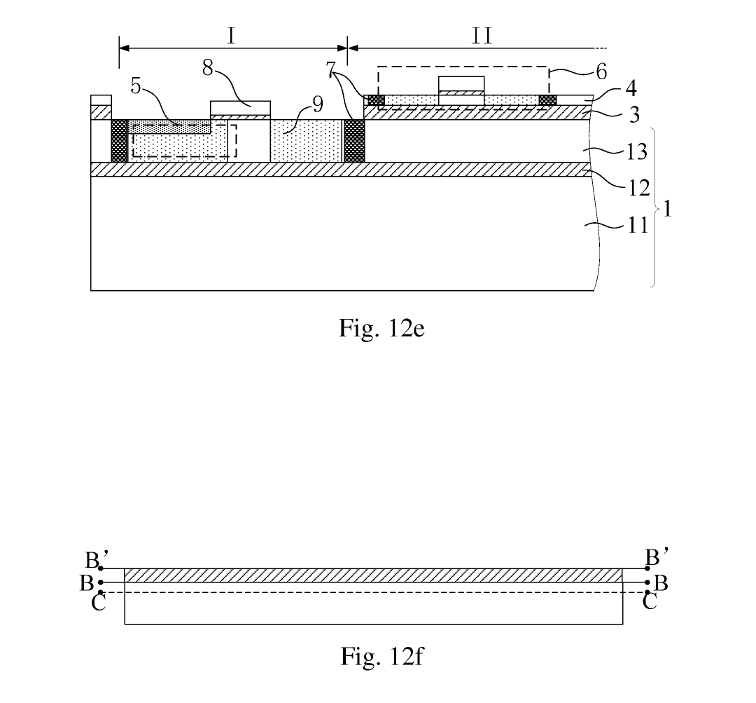

In this example, a material of the first top semiconductor layer 13 is the one used for fabricating semiconductor components, at least comprises any one of silicon, strained silicon, germanium, and silicon germanium; the first insulating buried layer 12 is a single layer or multi layer structure, wherein a material of each layer in the single layer or multi layer structure is any one in silicon oxide, nitride oxide, and silicon nitride and oxide; the first supporting substrate 11 is a common semiconductor substrate (at least comprises a silicon substrate or a sapphire substrate); the second semiconductor substrate 2 is a common semiconductor substrate (at least comprises a silicon substrate or a sapphire substrate) or a semiconductor substrate with an insulating buried layer (at least comprises a silicon-on-insulator or a germanium-on-insulator, and a silicon or a sapphire for its substrate material). In particular, in the example 4, the first top semiconductor layer 13 is silicon germanium; the first insulating buried layer 12 is silicon oxide and nitride with the single layer; the first supporting substrate 11 is a sapphire supporting substrate; and the second semiconductor substrate 2 is a silicon substrate, and a surface of the second semiconductor substrate 2 is illustrated as B-B (as illustrated in FIG. 12a).

It needs to be mentioned that, the first top semiconductor layer 13 is a thin film layer or thick film layer, wherein the thickness of the thin film is 0.1 μm-0.3 μm and the thickness of the thick film is 0.3 μm-10 μm. In the example 4, the first top semiconductor layer 13 is thick silicon germanium film with thickness of 0.3 μm-10 μm (optimized thickness is 5 μm-6 μm). A surface of the first top semiconductor layer 13 in the first top semiconductor layer 1 is illustrated as A′-A′ surface (as illustrated in FIG. 12a). Then execute step 2).

As illustrated in FIG. 12b, the second insulating buried layer 3 is fabricated on the surface of the first semiconductor substrate 1 in the step 2) (A-A surface in FIG. 12b is surface of the second insulating buried layer 3). The method of fabricating the second insulating buried layer 3 comprises: depositing material for the second insulating buried layer on the surface of the first semiconductor substrate 1, to fabricate the second insulating buried layer 3, using chemical vapor deposition or physical vapor deposition process; or thermal oxidizing the first semiconductor substrate 1 to fabricate oxide layer on the surface used as the second insulating buried layer 3.

It needs to be mentioned that, in another example, the second insulating buried layer 3 is fabricated on the surface of the second semiconductor substrate 2 in the step 2) (B′-B′ surface in FIG. 12f is surface of the second insulating buried layer 3). The method of fabricating the second insulating buried layer 3 comprises: depositing material for the second insulating buried layer on the surface of the second semiconductor substrate 2, to fabricate the second insulating buried layer 3, using chemical vapor deposition or physical vapor deposition process; or thermal oxidizing the second semiconductor substrate 2 to fabricate oxide layer on the surface used as the second insulating buried layer 3. In the example 4, the chemical vapor deposition process is used to fabricate material for the second insulating buried layer on the surface of the second semiconductor substrate 2 as the second insulating buried layer 3.

It needs to be mentioned that, the second insulating buried layer 3 is a single layer or multi layer structure, wherein material of each layer in the single layer or multi layer structure is any one in silicon oxide, nitride oxide, and silicon nitride and oxide. In the present example, the second insulating buried layer 3 is silicon nitride with the single layer. Then execute step 3).

As illustrated in FIG. 12c, the second insulating buried layer 3 is aligning bonded to the second semiconductor substrate 2 using common bonding technology in the step 3), after fabricating the second insulating buried layer 3 on the surface of the first semiconductor substrate 1. The common bonding technology is used to aligning bond the surface of the second semiconductor substrate 2 marked as the B-B surface (illustrated in FIG. 12a) and the surface of the second insulating buried layer 3 marked as A-A surface (illustrated in FIG. 12b), and then the second insulating buried layer 3 is set between the first top semiconductor layer 13 and the second semiconductor substrate 2. It needs to be mentioned that, in another embodiment, the common bonding technology is used to aligning bond the first top semiconductor layer 13 in the first semiconductor substrate 1 and the second insulating buried layer 3 after fabricating the second insulating buried layer 3 on the surface of the second semiconductor substrate 2 in the step 3) above. That is to say, in FIG. 12c, the common bonding technology is used to aligning bond the surface of the first top semiconductor layer 13 in the first semiconductor substrate 1 marked as the A′-A′ surface (illustrated in FIG. 12a) and the surface of the second insulating buried layer 3 marked as B′-B′ surface (illustrated in FIG. 120, and then the second insulating buried layer 3 is set between the first top semiconductor layer 13 and the second semiconductor substrate 2. Then execute step 4).

As illustrated in FIG. 12d, the second semiconductor substrate 2 is thinned and then the second top semiconductor layer 4 is fabricated in the step 4). The second top semiconductor layer 4 may be a thin film layer or thick film layer, wherein the thickness of the thin film layer is 0.1 μm-0.3 μm and the thickness of the thick film layer is 0.3 μm-10 μm. In the example 4, the first top semiconductor layer 13 is a thick film layer with thickness of 0.3 μm-10 μm (optimized thickness is 5 μm-6 μm), for the thin film layer with thickness of 0.1 μm-0.3 μm is selected as the second top semiconductor layer 4. It needs to be mentioned that, the thin film layer with thickness of 0.1 μm-0.3 μm is selected as the first top semiconductor layer 13, for the second top semiconductor layer 4 is a thick film layer with thickness of 0.3 μm-10 μm in another embodiment.

In the example 4, as illustrated in FIG. 12d, the first top semiconductor layer 13 is thick silicon germanium film layer with thickness of 0.3 μm-10 μm (optimized thickness is 5 μm-6 μm), the second semiconductor substrate 2 is silicon substrate, and the second top semiconductor layer 4 is thin silicon film layer with thickness of 0.1 μm-0.3 μm. It needs to be mentioned that the step 1) also comprises H ions implantation to the surface of the second semiconductor substrate 2. Depth of implantation is 0.1 μm-0.3 μm distance to the surface of the second semiconductor substrate 2 (C-C surface in FIG. 12a), and the depth of implantation is the thickness of the second top semiconductor layer 4. In the implantation process, high temperature annealing is used for thinning in the step 4), to implant the H ions to location of dielectric layer (as illustrated in FIG. 12c) and form continuous bubble layer. And then the second semiconductor substrate 2 is split at the location of dielectric layer formed by the H ions implantation (as illustrated in FIG. 12c), to form the second top semiconductor layer 4. Wherein the second top semiconductor layer 4 is thin silicon film layer with thickness of 0.1 μm-0.3 μm.

It needs to be specially mentioned that, the first top semiconductor layer 13 is a thin film layer with thickness of 0.1 μm-0.3 μm, and the second top semiconductor layer 4 is a thick film layer with thickness of 0.3 μm-10 μm in another example, it needs to be further mentioned that the step 1) also comprises H ions implantation to the surface of the second semiconductor substrate 2. Depth of implantation is 0.3 μm-10 μm distance to the surface of the second semiconductor substrate 2, and the depth of implantation is the thickness of the second top semiconductor layer 4. In the implantation process, high temperature annealing is used for thinning in the step 4), to implant the H ions to location of dielectric layer and form continuous bubble layer. And then the second semiconductor substrate 2 is split at the location of dielectric layer formed by the H ions implantation, to form the second top semiconductor layer 4. Wherein, the second top semiconductor layer 4 is a thick film layer with thickness of 0.3 μm-10 μm. Then execute the step 5).

As illustrated in FIG. 12e, two zones as zone I and zone II are defined on the surface of the second top semiconductor layer 4, and a window in the zone I is fabricated by etching to expose surface of the first top semiconductor layer 13 in the step 5). Wherein, common lithography and etch (including ICP or IRE at least) processes are used to fabricate the window in the zone I in this step. In the example 4, common lithography, ICP, and etch processes are used to fabricate the window in the zone I of the surface of the second top semiconductor layer 4, to expose the surface of the first top semiconductor layer 13. Then execute step 6).

As illustrated in FIG. 12e, in step 6), photosensitive components 5 and the pixel-readout circuit 6 are fabricated in the zone I and zone II. The photosensitive components 5 are fabricated in the thick film layer, and STI or dielectric isolation are used to fabricate the isolation 7 between the components, to fabricate the image sensor.

It needs to be mentioned that, the photosensitive components 5 comprise a photodiode (a photodiode with a PN junction or PIN junction) or a photo-electric gate at least, and are fabricated in the thick film layer; the pixel-readout circuit 6 is the 3T, 4T or other type readout circuit with MOS transistors; the 3T pixel-readout circuit comprises a reset transistor, an amplified transistor and a row select transistor fabricated in the thin film layer; the 4T pixel-readout circuit comprises a transfer transistor, a reset transistor, an amplified transistor and a row select transistor, wherein the transfer transistor is fabricated in the thick film layer and the reset transistor, amplified transistor and row select transistor are fabricated in the thin film layer. Particularly, as illustrated in FIG. 12e, the photosensitive components 5 is a photodiode with the PN junction, and the pixel-readout circuit 6 is the 4T type, wherein the reset transistor, amplified transistor and row select transistor are illustrated by only one transistor (see FIG. 12e). The zone for fabricating the transfer transistor 8, floating diffusion zone 9 in the 4T pixel-readout circuit is different to that for fabricating the reset transistor, amplified transistor and row select transistor.

In the example 4, the first top semiconductor layer 13 is thick silicon germanium film layer with thickness of 0.3 μm-10 μm (optimized thickness is 5 μm-6 μm), and the second top semiconductor layer 4 is s thin silicon film layer with thickness of 0.1 μm-0.3 μm. The window is fabricated to expose the surface of the first top semiconductor layer 13 in the zone I, and the zone II is in the second top semiconductor layer 4, as illustrated in FIG. 12e. The photosensitive components 5 is a photodiode with the PN junction fabricated in the zone I of the first top semiconductor layer 13 as the thick film layer. The pixel-readout circuit 6 is the 4T type, wherein the reset transistor, amplified transistor and row select transistor illustrated by only one transistor are fabricated in the zone II of the second top semiconductor layer 4 as the thin film layer. The transfer transistor 8, floating diffusion zone 9 in the 4T pixel-readout circuit are fabricated in the zone I of the first top semiconductor layer 13 as the thick film layer. The isolations 7 between the components are fabricated with dielectric isolation, to fabricate the image sensor.

In summary, the image sensor in the present invention has the advantages below:

1) The photosensitive components have a deeper PN junction depletion zone and a higher photo absorbing rate, for fabricated in the top semiconductor layer with the thick film layer.

2) The pixel-readout circuit has full depleted MOS transistors and the circuit is high speed, low energy consumption, avoiding latch-up effect, for fabricated in the top semiconductor layer with a thin film layer.

3) The photosensitive components and the pixel-readout circuit of the image sensor are electrical isolation by the first insulating buried layer and the second insulating buried layer to the first supporting substrate and the second supporting substrate, to enhance their ability of anti particles radiation with high energy.

So, the present invention overcomes disadvantages in the prior arts and is valuable for industry.

The present invention has been disclosed as the preferred embodiments above, however the above preferred embodiments are not described for limiting the present invention. Various modifications, alterations and improvements can be made by persons skilled in this art without departing from the spirits and principles of the present invention, and therefore the protection scope of the present invention is based on the range defined by the claims.

1. An image sensor comprising a semiconductor substrate, a photosensitive component, and a pixel-readout circuit, characterized in that,
the semiconductor substrate comprises a supporting substrate, and a first insulating buried layer, a first semiconductor layer, a second insulating buried layer, and a second semiconductor layer covered on the semiconductor substrate in sequence;
wherein, the first semiconductor layer and the second semiconductor layer have different thicknesses, and
the photosensitive component is in the thicker semiconductor layer, and the pixel-readout circuit is in the thinner semiconductor layer.

2. The image sensor of claim 1, characterized in that, the first semiconductor layer is thicker than the second semiconductor layer, the first semiconductor layer is a photosensitive layer, and the second semiconductor layer is a pixel-readout circuit layer.

3. The image sensor of claim 1, characterized in that, the second semiconductor layer is thicker than the first semiconductor layer, the second semiconductor layer is a photosensitive layer, and the first semiconductor layer is a pixel-readout circuit layer.

4. The image sensor of claim 1, characterized in that, the pixel-readout circuit is a 4T type CMOS pixel-readout circuit, which comprises a transfer transistor, a reset transistor, an amplified transistor and a row select transistor, wherein the transfer transistor is fabricated in the photosensitive layer, and the reset transistor, amplified transistor and row select transistor are fabricated in the pixel-readout circuit layer.

5. The image sensor of claim 1, characterized in that, a material for the first and second semiconductor layers is any one kind of silicon, strained silicon, germanium, or silicon germanium.

6. The image sensor of claim 5, characterized in that, the thickness of the photosensitive layer is 300 nm-10 μm, and the thickness of the pixel-readout circuit layer is 100 nm-300 nm.

7. A method of fabricating the image sensor comprising the following steps:
A, providing a semiconductor substrate with the first insulating buried layer, wherein the first insulating buried layer divides the semiconductor substrate into a supporting substrate and a top semiconductor layer;
B, fabricating the second insulating buried layer in the top semiconductor layer, to electrically isolate the top semiconductor layer to the first semiconductor layer and the second semiconductor layer, wherein the first semiconductor layer and the second semiconductor layer have different thicknesses;
C, defining two zones as a first zone and a second zone on a surface of the second semiconductor layer, wherein a window in the first zone is fabricated by etching to expose a surface of the first semiconductor layer; and
D, the first semiconductor layer and the second semiconductor layer have different thicknesses, and fabricating a photosensitive component and a pixel-readout circuit in the thicker and thinner semiconductor layers respectively.

8. The method of fabricating the image sensor of claim 7, characterized in that, the method is by an ion implantation in the top semiconductor layer for fabricating the second insulating buried layer.

9. The method of fabricating the image sensor of claim 7, characterized in that, the thickness of the top semiconductor layer is 0.5 μm-10 μm in the semiconductor substrate, the first semiconductor layer is thicker than the second semiconductor layer, and the thickness of the second semiconductor layer is 100 nm-300 nm.

10. The method of fabricating the image sensor of claim 7, characterized in that, the thickness of the top semiconductor layer is 0.2 μm-0.5 μm in the semiconductor substrate, the second semiconductor layer is thicker than the first semiconductor layer, and the thickness of the first semiconductor layer is 100 nm-300 nm.

11. The method of fabricating the image sensor of claim 10, characterized in that, after the step B and before the step C further comprises the following step: epitaxy on surface of the second semiconductor layer, to make the thickness is 0.3 μm-10 μm.

12. A method of fabricating the image sensor comprising the following steps:
A, providing a first semiconductor substrate and a second semiconductor substrate, wherein the first semiconductor substrate comprises a first supporting substrate, a first insulating buried layer on the surface of the first supporting substrate, and a first top semiconductor layer on the surface of the first insulating buried layer;
B, fabricating a second insulating buried layer on the surface of the first semiconductor substrate or the second semiconductor substrate;
C, bonding the first semiconductor substrate and the second semiconductor substrate, with the second insulating buried layer between the first top semiconductor layer and the second semiconductor substrate;
D, thinning the second semiconductor substrate to fabricate the second top semiconductor layer with different thicknesses to the first top semiconductor layer, wherein the thicker one in the first top semiconductor layer and the second top semiconductor layer is a thick film layer and the other one is a thin film layer on the contrary;
E, defining zone I and zone II on a surface of the second top semiconductor layer, and opening a window in the zone I until the surface of the first top semiconductor layer is exposed; and
F, fabricating the photosensitive components and the pixel-readout circuit in the zone I and zone II, wherein the photosensitive components are fabricated in the thick film layer and neighboring components are isolated, to finish fabricating the image sensor.

13. The method of fabricating the image sensor of claim 12, characterized in that, the first top semiconductor layer is a thin film layer with a thickness of 0.1 μm-0.3 μm, the second top semiconductor layer is a thick film layer with a thickness of 0.3 μm-10 μm.

14. The method of fabricating the image sensor of claim 12, characterized in that, the first top semiconductor layer is a thick film layer with a thickness of 0.3 μm-10 μm, the second top semiconductor layer is a thin film layer with a thickness of 0.1 μm-0.3 μm.

15. The method of fabricating the image sensor of claim 12, characterized in that, a material for the first top semiconductor layer and the second top semiconductor layer is a semiconductor material for fabricating semiconductor components, at least comprises any one kind of silicon, strained silicon, germanium, or silicon germanium; and the first supporting substrate is a common semiconductor substrate, at least comprises a silicon substrate or a sapphire substrate.

16. The method of fabricating the image sensor of claim 12, characterized in that, the photosensitive component comprises a photodiode or a photo-electric gate at least in step 6); and the pixel-readout circuit is a 3T or 4T type pixel-readout circuit, wherein the 3T pixel-readout circuit comprises a reset transistor, an amplified transistor and a row select transistor, and the 4T pixel-readout circuit comprises a transfer transistor, a reset transistor, an amplified transistor and a row select transistor.

17. The method of fabricating the image sensor of claim 16, characterized in that, the reset transistor, amplified transistor and row select transistor of the pixel-readout circuit are fabricated in the thin film layer; and the transfer transistor is fabricated in the thick film layer if the pixel-readout circuit is the 4T type pixel-readout circuit.

18. The method of fabricating the image sensor of claim 12, characterized in that, the second semiconductor substrate is a semiconductor substrate with an insulating buried layer, as least comprises a silicon-on-insulator or a germanium-on-insulator; and the thinning process in step 4) comprises etching the supporting substrate and the insulating buried layer of the second semiconductor substrate in sequence.

19. The method of fabricating the image sensor of claim 18, characterized in that, the thinning process in the step 4) also comprises a planarization process after etching.

20. The method of fabricating the image sensor of claim 13, characterized in that, the second semiconductor substrate is a common semiconductor substrate, which comprises a silicon substrate at least; and the thinning process in step 4) comprises an etching process forward and planarization process afterward.

21. The method of fabricating the image sensor of claim 12, characterized in that, the second semiconductor substrate is a common semiconductor substrate, which comprises a silicon substrate at least; and the step 1) further comprises an H ions implantation to a surface of the second semiconductor substrate, with a depth of implantation which is the thickness of the second top semiconductor layer in the step 4); and high temperature annealing is used for thinning in the step 4), to implant the H ions to location of a dielectric layer and form a continuous bubble layer, and then the second semiconductor substrate is split at the location of dielectric layer formed by the H ions implantation, to form the second top semiconductor layer.
